(19) United States
(12) Patent Application Publication
(10) Pub. No.: US 2023/0420430 A1
(43) Pub. Date: Dec. 28, 2023

(54) MODULAR POWER TRANSISTOR COMPONENT ASSEMBLIES WITH FLIP CHIP INTERCONNECTIONS

(71) Applicant: Wolfspeed, Inc., DUrham, NC (US)

(72) Inventors: Qianli Mu, San Jose, CA (US); Michael DeVita, Mesa, AZ (US); Alexander Komposch, Morgan Hill, CA (US); Basim Noori, San Jose, CA (US)

(21) Appl. No.: 17/848,500

(22) Filed: Jun. 24, 2022

(51) Int. Cl. H01L 25/16; H01L 23/055; H01L 23/367; H01L 23/498

(52) U.S. Cl. CPC H01L 25/165; H01L 23/055; H01L 23/367; H01L 23/49822

(57) ABSTRACT

A transistor device package includes a transistor die comprising a gate terminal, a drain terminal, and a source terminal, and a passive component assembly including the transistor die on a surface thereof and comprising one or more passive electrical components electrically coupled to the gate terminal, the drain terminal, and/or the source terminal. A mold structure may be provided on the one or more passive electrical components. One or more conductive pads may be exposed by the mold structure. A support structure may extend along one or more sides of the transistor die on the surface of the passive component assembly. The support structure may provide a cavity that extends around the transistor die, and/or may be thermally conductive. Related devices and component assemblies are also discussed.

### FIELD

The present disclosure is directed to transistor devices, and more particularly, to structures for transistor device packaging.

### BACKGROUND

Power amplifiers are used in a variety of applications such as base stations for wireless communication systems, multi-stage and multiple-path amplifiers (e.g., Doherty amplifiers), etc. The signals amplified by the RF power amplifiers often include signals that have a modulated carrier having frequencies in the megahertz (MHz) to gigahertz (GHz) range. For example, Electrical circuits requiring high power handling capability while operating at high frequencies, such as R-band (0.5-1 GHz), S-band (3 GHz), X-band (10 GHz), Ku-band (12-18 GHz), K-band (18-27 GHz), Ka-band (27-40 GHz) and V-band (40-75 GHz) have become more prevalent. In particular, there is now a high demand for radio frequency (“RF”) transistor amplifiers that are used to amplify RF signals at frequencies of, for example, 500 MHz and higher (including microwave frequencies).

Many power amplifier designs utilize semiconductor switching devices as amplification devices. Examples of these switching devices include power transistor devices, such as MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally-diffused metal-oxide semiconductor) transistors, etc. A power amplifier may also include passive matching networks at the input and output nodes of the active power transistor devices.

The transistor devices are typically formed as semiconductor integrated circuit chips. Transistor devices may be implemented, for example, in silicon or using wide bandgap semiconductor materials (i.e., having a band-gap greater than 1.40 eV), such as silicon carbide (“SiC”) and Group III nitride materials. As used herein, the term “Group III nitride” refers to those semiconducting compounds formed between nitrogen and the elements in Group III of the periodic table, usually aluminum (Al), gallium (Ga), and/or indium (In). The term also refers to ternary and quaternary compounds, such as AlGaN and AlInGaN. These compounds have empirical formulas in which one mole of nitrogen is combined with a total of one mole of the Group III elements.

Silicon-based RF transistor amplifiers may typically be implemented using LDMOS transistors, and can exhibit high levels of linearity with relatively inexpensive fabrication. Group III nitride-based RF amplifiers may typically be implemented using HEMTs, primarily in applications requiring high power and/or high frequency operation where LDMOS transistor amplifiers may have inherent performance limitations.

RF transistor amplifiers may include one or more amplification stages, with each stage typically implemented as a transistor amplifier. In order to increase the output power and current handling capabilities, RF transistor amplifiers are typically implemented in a “unit cell” configuration in which a large number of individual “unit cell” transistors are electrically connected (e.g., in parallel). An RF transistor amplifier may be implemented as a single integrated circuit chip or “die,” or may include a plurality of dies. A die or chip may include a small block of semiconducting material or other substrate in which electronic circuit elements are fabricated. For example, a plurality of individual power transistor devices may be formed on a relatively large semiconductor substrate (e.g., by growing epitaxial layers there on doping selected regions with dopants, forming insulation and metal layers thereon, etc.) and the completed structure may then be cut (e.g., by a sawing or dicing operation) into a plurality of individual die. When multiple RF transistor amplifier dies are used, they may be connected in series and/or in parallel.

RF transistor amplifiers often include matching circuits, such as impedance matching circuits, that are designed to improve the impedance match between the active transistor die (e.g., including MOSFETs, HEMTs, LDMOS, etc.) and transmission lines connected thereto for RF signals at the fundamental operating frequency, and harmonic termination circuits that are designed to at least partly terminate harmonic products that may be generated during device operation such as second and third order harmonic products. The termination of the harmonic products also influences generation of intermodulation distortion products.

The RF amplifier transistor die(s) as well as the impedance matching and harmonic termination circuits may be enclosed in a device package. Integrated circuit packaging may refer to encapsulating one or more dies in a supporting case or package (e.g., overmold or open-cavity packages) that protects the dies from physical damage and/or corrosion, and supports the electrical contacts for connection to external circuits. The input and output impedance matching circuits in an integrated circuit device package typically include LC networks that provide at least a portion of an impedance matching circuit that is configured to match the impedance of the active transistor die to a fixed value. Electrical leads may extend from the package to electrically connect the RF amplifier to external circuit elements such as input and output RF transmission lines and bias voltage sources.

Some conventional methods for assembling RF power devices may involve assembling the transistor die and some of the matching network components in a ceramic or over-molded package on a CPC (copper, copper-molybdenum, copper laminate structure) or copper flange. The transistor die, capacitors, and input/output leads may be interconnected with wires, such as gold and/or aluminum wires. Such an assembly process may be slow and sequential (e.g., one package bonded at a time), and assembly costs may be high (e.g., due to cost of gold wires and expensive wire-bond machines).

### SUMMARY

According to some embodiments, a transistor device package includes a transistor die comprising a gate terminal, a drain terminal, and a source terminal, a passive component assembly including the transistor die on a surface thereof and comprising one or more passive electrical components electrically coupled to the gate terminal, the drain terminal, and/or the source terminal, and a thermally conductive support structure on the surface of the passive component assembly and extending along one or more sides of the transistor die.

In some embodiments, the thermally conductive support structure provides a cavity that extends around the transistor die.

In some embodiments, a first surface of the transistor die is on the surface of the passive component assembly, and a substrate is on a second surface of the transistor die opposite the first surface. The thermally conductive support structure extends between the substrate and the passive component assembly.

In some embodiments, the substrate comprises a thermally conductive material. The thermally conductive structure provides a first heat conduction path, and the second surface of the transistor die provides a second heat conduction path.

In some embodiments, the surface of the passive component assembly including the transistor die thereon is a second surface, the one or more passive electrical components are on a first surface of the passive component assembly opposite the second surface, and the passive component assembly comprises conductive traces and/or vias that electrically couple the one or more passive electrical components on the first surface thereof to the gate terminal, the drain terminal, and/or the source terminal of the transistor die on the second surface thereof.

In some embodiments, the passive component assembly further comprises a mold structure on the one or more passive electrical components on the first surface thereof, and one or more conductive pads that are exposed by the mold structure.

In some embodiments, the second surface of the passive component assembly is free of the mold structure.

In some embodiments, the passive component assembly further comprises first and second package leads on the first or second surface, and the one or more passive electrical components are electrically coupled between the gate terminal and the first package lead or between the drain terminal and the second package lead.

In some embodiments, the thermally conductive support structure comprises an electrically insulating material.

In some embodiments, the thermally conductive support structure comprises copper, aluminum, and/or silicon carbide.

In some embodiments, the one or more passive electrical components comprise a surface mount device and/or an integrated passive device.

In some embodiments, the gate terminal, the drain terminal, and the source terminal comprise conductive pillar structures adjacent the surface of the passive component assembly and electrically coupled to the one or more passive electrical components by conductive bumps.

In some embodiments, the surface of the passive component assembly comprises an integral support structure that provides a cavity extending around the transistor die, and the thermally conductive support structure is within the integral support structure.

According to some embodiments, a transistor device package includes a transistor die comprising a gate terminal, a drain terminal, and a source terminal, and a passive component assembly comprising one or more passive electrical components electrically coupled to the gate terminal, the drain terminal, and/or the source terminal. The transistor die is on a surface of the passive component assembly, and the surface of the passive component assembly comprises a support structure that provides a cavity extending around the transistor die.

In some embodiments, the support structure comprises an electrically insulating material.

In some embodiments, the support structure comprises an integral portion of the passive component assembly that protrudes from the surface.

In some embodiments, a first surface of the transistor die is on the surface of the passive component assembly, and a substrate is on a second surface of the transistor die opposite the first surface. The support structure extends between the substrate and the passive component assembly.

In some embodiments, the substrate comprises a thermally conductive material, the support structure includes a thermally conductive structure extending therein that provides a first heat conduction path, and the second surface of the transistor die provides a second heat conduction path.

In some embodiments, the surface of the passive component assembly including the transistor die thereon is a second surface, and the one or more passive electrical components are on a first surface of the passive component assembly opposite the second surface.

In some embodiments, the passive component assembly further comprises a mold structure on the one or more passive electrical components on the first surface thereof, and one or more conductive pads that are exposed by the mold structure.

In some embodiments, the second surface of the passive component assembly is free of the mold structure and comprises first and second package leads thereon.

According to some embodiments, a transistor device package includes an active component assembly comprising a transistor die having a gate terminal, a drain terminal, and a source terminal, a passive component assembly including the active component assembly on a surface thereof and comprising one or more passive electrical components electrically coupled to the gate terminal, the drain terminal, and/or the source terminal, a mold structure on the one or more passive electrical components, and a frame structure providing a cavity that extends around the transistor die.

In some embodiments, a first surface of the transistor die is on the surface of the passive component assembly, and a substrate is on a second surface of the transistor die opposite the first surface. The frame structure extends between the substrate and the passive component assembly.

In some embodiments, the cavity is an air cavity defined by the frame structure and the substrate.

In some embodiments, the cavity is filled with an encapsulant that extends around the transistor die.

In some embodiments, the frame structure and the substrate respectively comprise a thermally conductive material, the frame conductive structure provides a first heat conduction path, and the second surface of the transistor die provides a second heat conduction path.

In some embodiments, the frame structure and the substrate comprise a unitary structure.

In some embodiments, the surface of the passive component assembly including the transistor die thereon is a second surface, and the one or more passive electrical components are on a first surface of the passive component assembly opposite the second surface.

In some embodiments, the passive component assembly comprises one or more conductive pads are exposed by the mold structure.

In some embodiments, the second surface of the passive component assembly is free of the mold structure and comprises first and second package leads thereon.

According to some embodiments, a passive component assembly includes one or more passive electrical components on a surface of an interconnect structure, where the interconnect structure is configured to electrically couple the one or more passive electrical components to a gate terminal, drain terminal, and/or source terminal of a transistor die. A mold structure is on the one or more passive electrical components on the surface of the interconnect structure, and one or more conductive pads are electrically coupled to the one or more passive electrical components and are exposed by the mold structure.

In some embodiments, the surface of the interconnect structure comprising the one or more passive electrical components and the mold structure thereon is a first surface, and the interconnect structure comprises a second surface opposite the first surface that is configured to accept the transistor die.

In some embodiments, the second surface of the passive component assembly comprises the one or more conductive pads thereon.

In some embodiments, the second surface is free of the mold structure.

In some embodiments, the one or more conductive pads are arranged in a ground-signal-ground layout.

In some embodiments, the one or more passive electrical components are configured to be electrically tested via the one or more conductive pads prior to electrically connecting the transistor die to the passive component assembly.

In some embodiments, the one or more passive electrical components comprise a surface mount device and/or an integrated passive device.

In some embodiments, the second surface of the interconnect structure is configured to electrically couple the one or more passive electrical components to the gate terminal, drain terminal, and/or source terminal of the transistor die by conductive bumps.

In some embodiments, the second surface of the interconnect structure comprises a support structure that provides a cavity configured to accept the transistor die.

In some embodiments, the support structure comprises an electrically insulating material.

In some embodiments, the support structure comprises an integral portion of the interconnect structure that protrudes from the second surface.

In some embodiments, the support structure comprises a thermally conductive material.

In some embodiments, the transistor die is a Group III nitride-based RF transistor amplifier die.

In some embodiments, an operating frequency of the RF transistor amplifier is in the R-band, S-band, X-band, Ku-band, K-band, Ka-band, and/or V-band.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

FIG. 1A is a schematic cross-sectional view of a transistor device in accordance with some embodiments of the present disclosure, shown by way of example as a high electron mobility transistor die.

FIG. 1B is a schematic cross-sectional view taken along line I-I′ of FIG. 1A that shows the structure of the top metallization of the transistor die of FIG. 1A.

FIGS. 2A, 2B, 2C, 2D, 2E, and 2F are schematic cross-sectional views illustrating various examples of active component assemblies according to some embodiments of the present disclosure.

FIGS. 3A, 3B, 3C, 3D, 3E, and 3F are schematic cross-sectional views illustrating various examples of passive component assemblies according to some embodiments of the present disclosure.

FIGS. 4A, 4B, 4C, 4D, and 4E are schematic diagrams illustrating various examples of packaging components according to some embodiments of the present disclosure.

FIGS. 5A and 5B are schematic cross-sectional views illustrating various examples of packaged power transistor devices including active and passive component assemblies on the same surface according to some embodiments of the present disclosure.

FIGS. 6A, 6B, 6C, 6D, and 6E are schematic cross-sectional views illustrating various examples of packaged power transistor devices including active and passive component assemblies on the opposite surfaces according to some embodiments of the present disclosure.

FIGS. 7A, 7B, 7C, 7D, and 7E are bottom plan views illustrating the packaged power transistor devices of FIGS. 6A, 6B, 6C, 6D, and 6E, respectively, with the carrier substrate removed.

FIGS. 8 and 9 are flowchart diagrams illustrating example operations for fabricating packaged power transistor devices including modular active and passive component assemblies according to some embodiments of the present disclosure.

FIGS. 10A, 10B, and 10C are schematic circuit diagrams illustrating various circuit topologies that may be implemented by combinations of active and passive component assemblies according to some embodiments of the present disclosure.

### DETAILED DESCRIPTION

In the following detailed description, numerous specific details are set forth to provide a thorough understanding of embodiments of the present disclosure. However, it will be understood by those skilled in the art that the present disclosure may be practiced without these specific details. In some instances, well-known methods, procedures, components, and circuits have not been described in detail so as not to obscure the present disclosure. It is intended that all embodiments disclosed herein can be implemented separately or combined in any way and/or combination. Aspects described with respect to one embodiment may be incorporated in different embodiments although not specifically described relative thereto. That is, all embodiments and/or features of any embodiments can be combined in any way and/or combination.

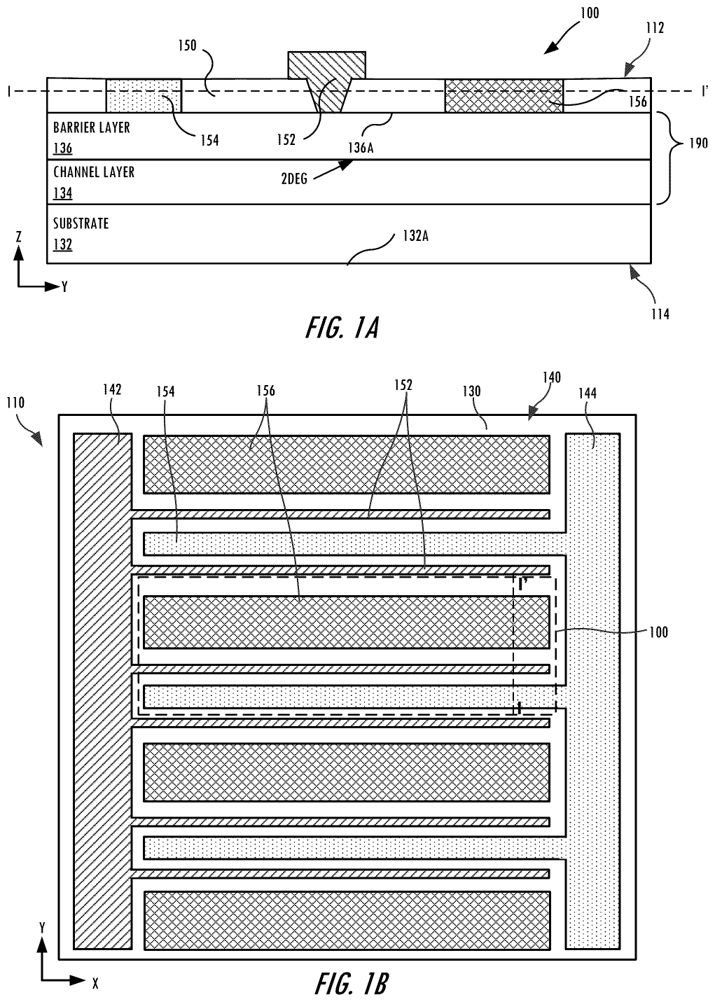

FIG. 1A is a schematic cross-sectional view of a unit cell 100 of a transistor device in accordance with some embodiments of the present disclosure, shown by way of example as a high electron mobility transistor (HEMT). While described herein with reference to HEMTs by way of example, it will be understood that embodiments of the present disclosure are not limited to any particular transistor type, and may include, for example, metal-oxide-semiconductor field effect transistor (MOSFET) embodiments, such as laterally diffused MOSFETs (LDMOS) embodiments.

As shown in FIG. 1A, the high electron mobility transistor 100 may be formed on a substrate 132 such as, for example, a silicon carbide, silicon, or sapphire substrate. A channel layer 134 is formed on the substrate 132. A barrier layer 136 is formed on the channel layer 134 opposite the substrate 132. The channel layer 134 may include, for example, gallium-nitride (GaN) and the barrier layer 126 may include, for example, aluminum gallium-nitride (AlGaN).

The channel layer 134 and barrier layer 136 may together form a semiconductor structure 190 on the substrate 132. A source contact 156 and a drain contact 154 are formed on an upper surface of the barrier layer 136 and are laterally spaced apart from each other. The source contact 156 and the drain contact 154 may each form an ohmic contact to the barrier layer 136.

A gate contact 152 is formed on the upper surface of the barrier layer 136 between the source contact 156 and the drain contact 154. A two-dimensional electron gas (2DEG) layer is formed at a junction between the channel layer 134 and the barrier layer 136 when the HEMT device 110 is biased to be in its conducting or “on” state. The 2DEG layer acts as a highly conductive layer that allows current to flow between the source and drain regions of the device that are beneath the source contact 156 and the drain contact 154, respectively. The source contact 156 may be coupled to a reference signal such as, for example, a ground voltage.

In some embodiments, one or more insulating layers 150 may directly contact the upper surface of the semiconductor structure 190 (e.g., contact the upper surface 136A of the barrier layer 136). The one or more insulating layers 150 may serve as passivation layers for the HEMT device 110.

In some embodiments, additional metal contacts (not shown) may be provided to contact the gate contact 152, the drain contact 154, and/or the source contact 156. For example, conductive pillar structures (e.g., copper pillars) may protrude from the front surface 112 of the HEMT device 100 to provide electrical connections between the gate contact 152, the drain contact 154, and/or the source contact 156 and an external device or module, such as the passive component assemblies described herein.

FIG. 1B is a schematic cross-sectional view of a transistor die 110 that is taken through a portion of a top side metallization structure 140. Dielectric layers that isolate the various conductive elements of the top-side metallization structure 140 from each other are not shown in FIG. 1B to simplify the drawing. It will be appreciated that FIGS. 1A and 1B (and various of the other figures) are highly simplified diagrams and that actual RF amplifiers may include many more unit cells and various circuitry and elements that are not shown in the simplified figures herein.

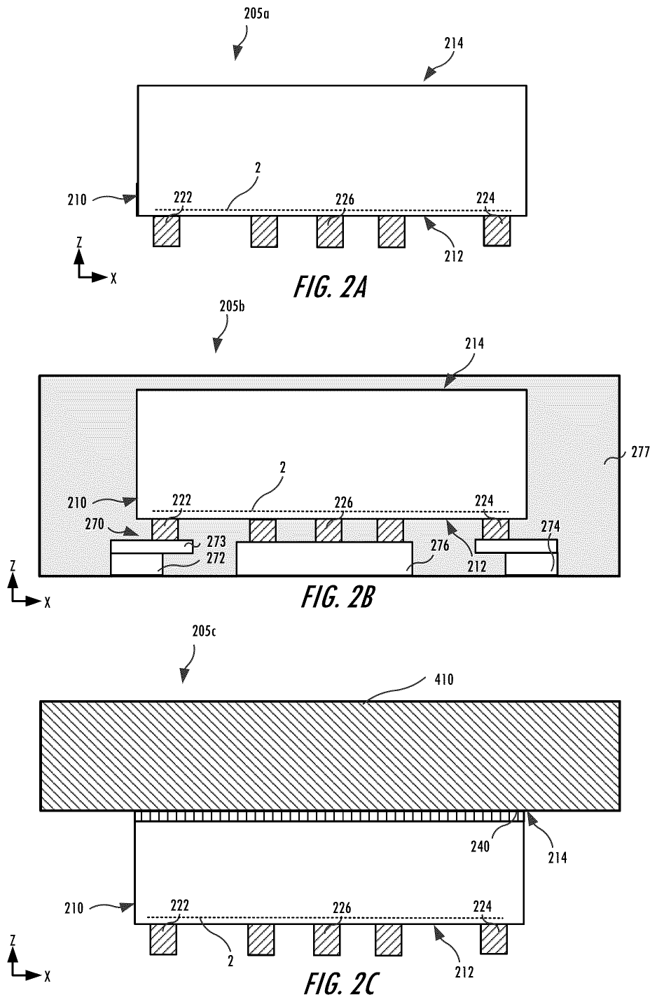

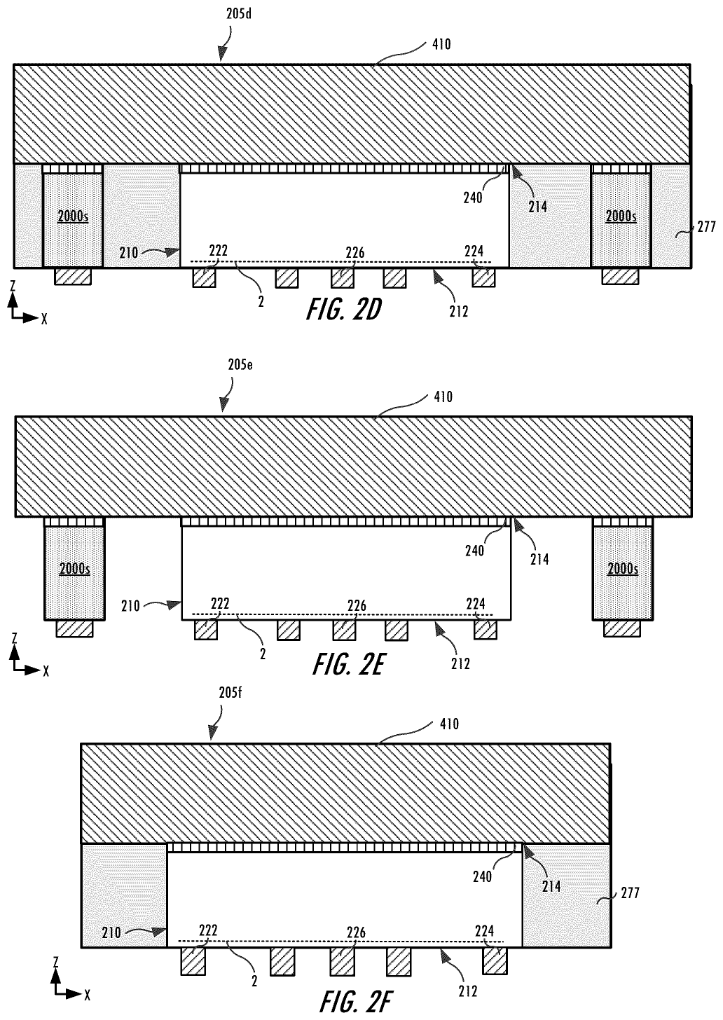

As shown in FIG. 1B, a transistor device or die 110 may include multiple transistor unit cells or structures 100 that are connected in parallel to device terminals or electrodes (e.g., an input terminal, an output terminal, and a ground terminal). For example, each of the gate 152, drain 154, and source 156 contacts may extend in a first direction (e.g., the X-direction) to define gate, drain, and/or source ‘fingers’, which may be connected by one or more respective buses (e.g., by a gate bus and a drain bus on an upper surface 136A of a semiconductor structure 190. In particular, the gate fingers 152 are electrically connected to a common gate manifold 142, and the drain fingers 154 are electrically connected to a common drain manifold 144. The gate manifold or bus 142 is electrically connected to a gate terminal 222, which may be implemented as one or more gate pillars (see FIG. 2A), and the drain manifold or bus 144 is electrically connected to the drain terminal 224, which may be implemented as one or more drain pillars (see FIG. 2A). The source fingers 156 are electrically connected to the source terminal 226, which may be implemented by one or more source pillars (see FIG. 2A).

In FIG. 1B, the gate fingers 152, drain fingers 154, and source fingers 156 extend in parallel to each other, with the gate fingers 152 extending from the gate bus 142 in a first direction and the drain fingers 154 extending from the drain bus 144 in a direction opposite the first direction. Each gate finger 152 may be positioned between a drain finger 154 and a source finger 156 to define the unit cell 100. The gate fingers 152, drain fingers 154, and source fingers 156 (and connecting buses) may define part of gate-, drain-, and source-connected electrodes of the device, respectively, as defined by the top metallization structure 140. Since the gate fingers 152 are electrically connected to a common gate bus 142, the drain fingers 154 are electrically connected to a common drain bus 144, and the source fingers 156 are electrically connected together, it can be seen that the unit cell transistors 100 are electrically connected together in parallel. One of the terminals of the device (e.g., a source terminal 226 connected to the source contact(s) 156) may be configured to be coupled to a reference signal such as, for example, an electrical ground.

As noted above, Group III nitride-based transistor devices, including the HEMT device 100 illustrated in FIG. 1A, are often used in high power and/or high frequency applications, such as RF (radio frequency) applications. Typically, high levels of heat are generated within the Group III nitride-based RF amplifier die(s) during operation. If the RF die(s) become too hot, the performance (e.g., output power, efficiency, linearity, gain, etc.) of the RF amplifier may deteriorate and/or the RF amplifier die(s) may be damaged. Also, as noted above, wirebond-based package assembly may be slow and/or expensive.

Pursuant to embodiments of the present disclosure, transistor devices, such as Group III nitride-based RF transistor amplifiers, include transistor dies that have one or more of their gate terminals, drain terminals, and source terminals located on the same (e.g., the “front”) side or surface of the transistor die, adjacent the active channel or active area. The transistor dies may not require bond wires for the gate and drain connections, which may reduce an amount of inductance present in the circuit, which may be advantageous in some applications. In addition, the top side gate, drain, and/or source contacts may allow for modular assembly techniques, for example, such that modules or assemblies can be coupled directly to the gate, drain, and/or source terminals of the RF transistor amplifier dies.

The modules or assemblies may be implemented as active modules or active component assemblies (which may include the active transistor die and coupling elements or structures thereon) and passive modules or passive component assemblies (which may include one or more passive electrical components that can provide additional circuitry, such as harmonic termination circuitry, input impedance matching circuitry, and/or output impedance matching circuitry). The active component assembly may be provided on a surface of the passive component assembly (e.g. on a back surface, opposite to the front surface on which the passive electrical components are provided). For example, the active module may include an active GaN on SiC die and redistribution layer (RDL) or heat spreader mounted on a surface of the passive module. The active module and passive module may be coupled by flip chip connection. As used herein, “flip chip” may refer to a configuration in which pads or terminals of a transistor device or other components are electrically connected by conductive bumps or pillars (rather than by wirebonds), which can allow for stacked or vertical connections with one or more other circuit elements.

The passive module may include various passive electrical components, implemented by discrete devices (e.g., surface mount devices (SMDs), integrated passive devices (IPDs) with thin film substrates such as silicon, alumina, or glass) in a flip chip configuration and/or by elements integrated in a multi-layer laminate structure (e.g., spiral inductors, plate or interdigitated capacitors, laminate-based transmission lines, etc.) to provide impedance matching and/or harmonic termination. The passive module may also include conductive pads (also referred to herein as interconnection pads) that are exposed (e.g., outside of or not covered by an overmold structure that covers the passive electrical components) so as to be accessible for electrical testing and screening before integration with the active modules, which may improve yield and reduce product costs.

A frame structure (which may be integral to or additionally provided on the surface of the passive component assembly on which the die is mounted) may extend around the active module for environmental protection and/or thermal conduction. Where the substrate of the transistor die (e.g., on the “back” side or inactive surface of the die) has a high thermal conductivity, such as a SiC growth substrate for a Group III nitride based HEMT, the active component assembly may include a thermally conductive carrier substrate or submount, such as a metal slug, leadframe, or flange, mounted on the bottom side or surface of the transistor die to provide improved thermal dissipation of the heat generated by the die from the amplifier package.

The frame structure may not only offer environmental protection of the die and mechanical support to the laminate or other interconnect structure for assembly flexibility, but may also provide an additional heat extraction path (i.e., in addition to the thermal path from the inactive surface of the transistor die to the flange) when formed of a material having high thermal conductivity and coupled to the thermally conductive carrier substrate. That is, the modular assembly may be configured to provide multiple thermal conduction paths for heat removal, which may allow for improved thermal performance and capabilities.

Embodiments of the present disclosure may also provide electrical ground paths separate from the main heat conduction path (e.g., by providing the source terminals on the front surface of the transistor die, and providing the heat conduction path(s) by coupling the frame structure and/or back surface of the transistor die to the thermally conductive substrate), which may otherwise be difficult or impossible to achieve without a flip chip interconnection scheme. Also, implementing the active and passive components of a packaged device as modular assemblies (with separate active and passive modules) and exposed test pads may allow for electrical testing and/or screening before final packaging/assembly, which can improve yield and reduce costs. Embodiments of the present disclosure may allow for stacked component connections (e.g., in the Z-direction), in some embodiments with an active components surrounded by an air cavity defined by a frame structure, passive components packaged in a mold structure, and package leads and/or test pads integrated on a surface (e.g., on the back side) of the passive component assembly or otherwise exposed by the mold structure and the frame structure. As used herein, the terms air cavity and open cavity may be used interchangeably to refer to a packaging structure in which components (e.g., transistor dies 210, passive devices 350, etc.) are enclosed in or protected by an air gap or air space (i.e., where one or more surfaces of the components do not physically contact another element), in contrast with encapsulation or protection by a mold structure where the encapsulant material physically contacts multiple surfaces of the components.

FIGS. 2A to 2F illustrate various examples of active component assemblies 205a to 205f (collectively 205) according to some embodiments of the present disclosure. As shown in FIG. 2A, an example active component assembly 205a may include an active die 210 (e.g., a Group III-nitride or SiC-based semiconductor die). The gate terminal 222, drain terminal 224, and/or source terminal 226 may be implemented by conductive pillar structures (e.g., copper pillars). In the example of FIG. 2A, all of the conductive pillar structures 222, 224, 226 protrude from a first or active surface 212 of the die 210, i.e., the “top” surface 212 adjacent the active channel 2 (e.g., the 2DEG layer). FIG. 2A thus illustrates a flip-chip configuration of the active die 210, with the contacts 222, 224, and 226 on one side 212 of the die 210 (e.g., facing “down” when mounted on a passive component assembly described herein, in some embodiments using an underfill material for support), and the growth substrate on the opposite side 214 (e.g., facing “up” when mounted on the passive component assembly). However, it will be understood that one or more of the gate terminal 222, drain terminal 224, and source terminal 226 may protrude from or may otherwise be implemented on the second or inactive surface 214 of the die 210, for example, using conductive via structures extending through or between surfaces 212, 214 of the die 210.

FIG. 2B illustrates an example active component assembly configuration 205b in which the die 210 including the conductive pillar structures 222, 224, 226 are electrically connected to a coupling element 270. The coupling element 270 includes a gate connection pad 272, a drain connection pad 274, and a source connection pad 276. The conductive patterns 273 electrically connect the gate connection pad 272 and the drain connection pad 274 to the gate terminal 222 and the drain terminal 224 of the transistor amplifier die 210. An encapsulating structure 277 provides a package including the die 210 and the coupling element 270. For example, the die 210 and the coupling element 270 may be implemented in a RDL package. The encapsulating material 277 may be formed of a plastic or a plastic polymer compound, but the present disclosure is not limited thereto. In some embodiments, the encapsulating material 277 may include a polymer with fillers. In the example shown in FIG. 2B, the connection pads 272, 274, 276 and conductive patterns 273 are arranged in a fan-out configuration that increases separation of the connections to the respective source, gate, and drain terminals, but it will be understood that other configurations (e.g., a fan-in configuration) may be similarly implemented.

FIG. 2C illustrates an example active component assembly configuration 205c in which the conductive pillar structures 222, 224, 226 protrude from the first or active surface 212 of the die 210, and the second or inactive surface 214 of the die 210 is mounted on a carrier substrate 410 (e.g., a thermally conductive substrate such as a metal slug, leadframe, or flange). The thermally conductive substrate 410 can provide improved thermal dissipation of the heat generated by the die 210 from the amplifier package. For example, the substrate 410 may be a package level heat slug that is configured to pull heat away from the die 210 and toward an external heat sink. In some package configurations, the carrier substrate 410 also serves as an electrical terminal that provides a reference potential (e.g., ground) to the dies that are mounted thereon. For example, the substrate 410 may be a CPC (copper, copper-molybdenum, copper laminate structure) or copper flange.

FIG. 2D illustrates an example active component assembly configuration 205d in which the conductive pillar structures 222, 224, 226 protrude from the first or active surface 212 of the die 210, and the second or inactive surface 214 of the die 210 is mounted on the thermally conductive substrate 410 along with one or more mechanical support structure(s) 2000s. The mechanical support structure(s) 2000s may extend along or adjacent one or more sides of the die 210, and in some embodiments may define a frame or ring shape that provides or form an open or air cavity around the die 210. The mechanical support structure(s) 2000s may have a thickness substantially similar to a thickness of the die 210, and can provide improved mechanical support (e.g., for stacking the active component assembly 205d on a passive component assembly). In some embodiments, the mechanical support structure(s) 2000s may be formed of one or more materials that may improve thermal conduction. In the example of FIG. 2D, an encapsulating structure 277 is formed around the die 210 and mechanical support structure(s) 2000s to provide additional support. In the example of FIG. 2E, the encapsulating structure 277 is omitted from in the active component assembly 205e.

FIG. 2F illustrates an example active component assembly configuration 205f in which the conductive pillar structures 222, 224, 226 protrude from the first or active surface 212 of the die 210, the second or inactive surface 214 of the die 210 is mounted on the thermally conductive substrate 410, and an encapsulating structure 277 is formed around the die 210. The encapsulating structure 277 may have a thickness substantially similar to a thickness of the die 210, and can provide improved mechanical support to provide additional support (e.g., for stacking the active component assembly 205f on a passive component assembly).

In any of the example active component assemblies 205a, 205b, 205c, 205d, 205e, 205f, the die 210 may be mounted in a flip chip arrangement on a surface 312, 314 of a passive component assembly 305, that is, with the gate terminal 222, the drain terminal 224, and the source terminal 226 facing the surface of the passive component assembly 305. In the example of FIG. 2B, the coupling element 270 may be provided between the first surface 212 of the die and the passive component assembly 305. Also, while illustrated in FIGS. 2A to 2E with reference to specific examples, features of one or more the example active component assemblies 205a, 205b, 205c, 205d, 205e, 205f may be combined in some embodiments. For example, the inactive surface 214 of the die 210 may be exposed by the encapsulating structure 277 in the active component assembly 205b of FIG. 2B, and may be mounted on the thermally conductive substrate 410 of FIG. 2C.

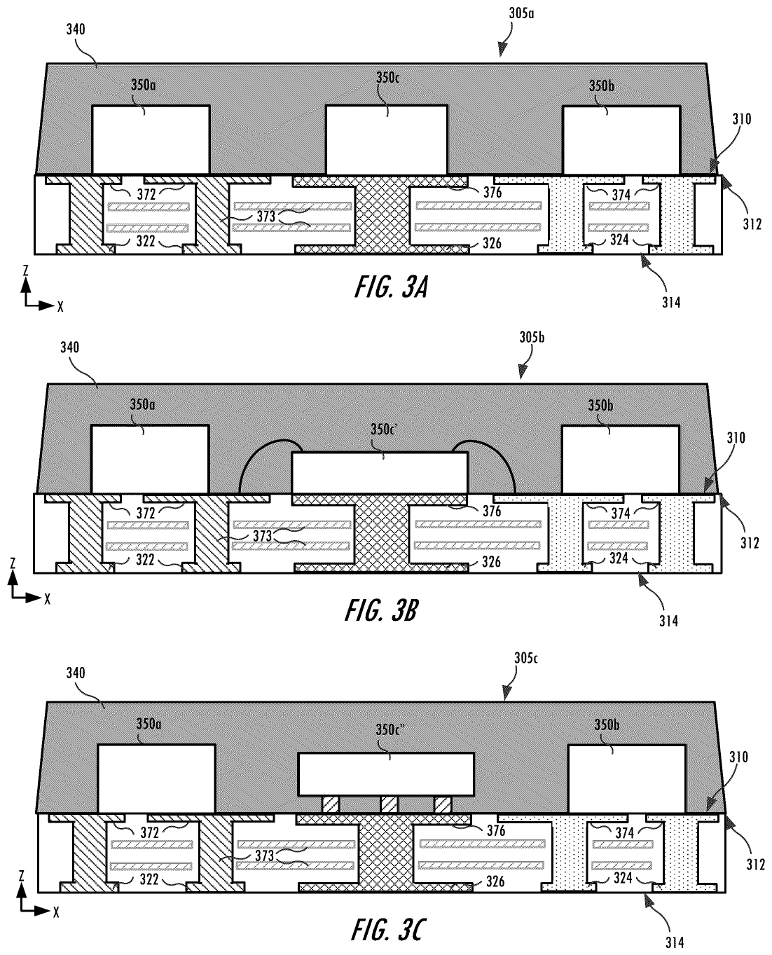

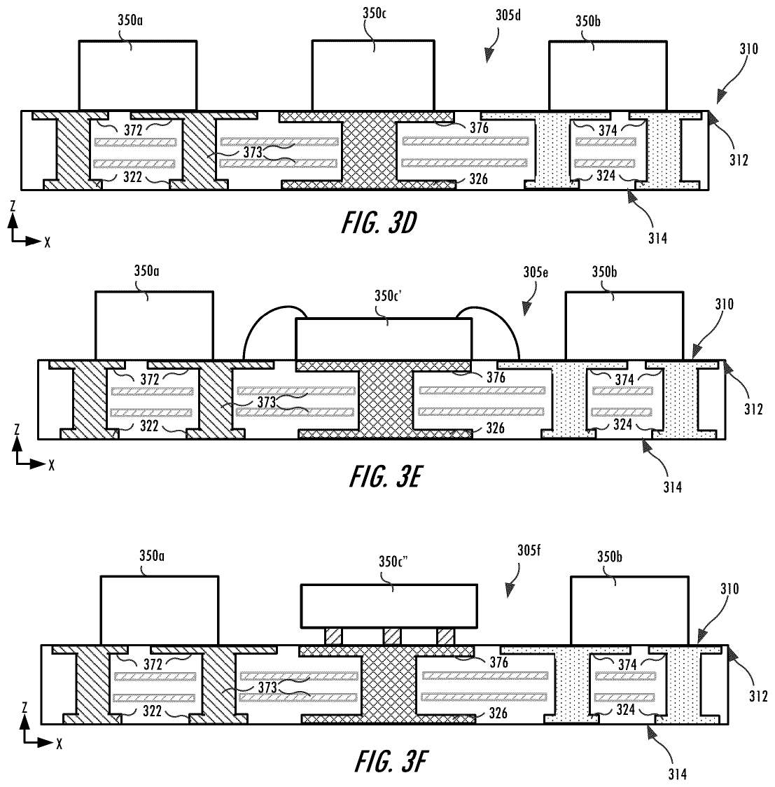

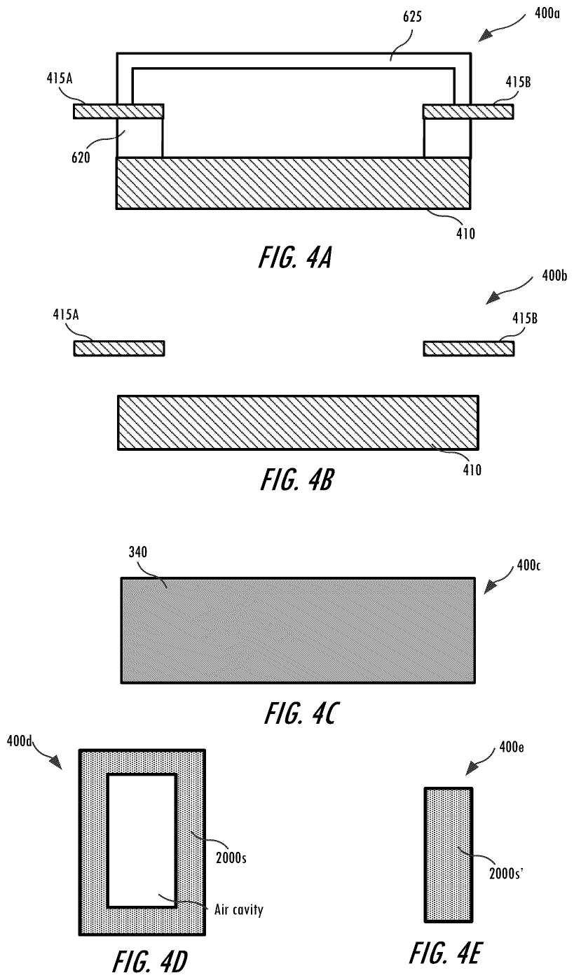

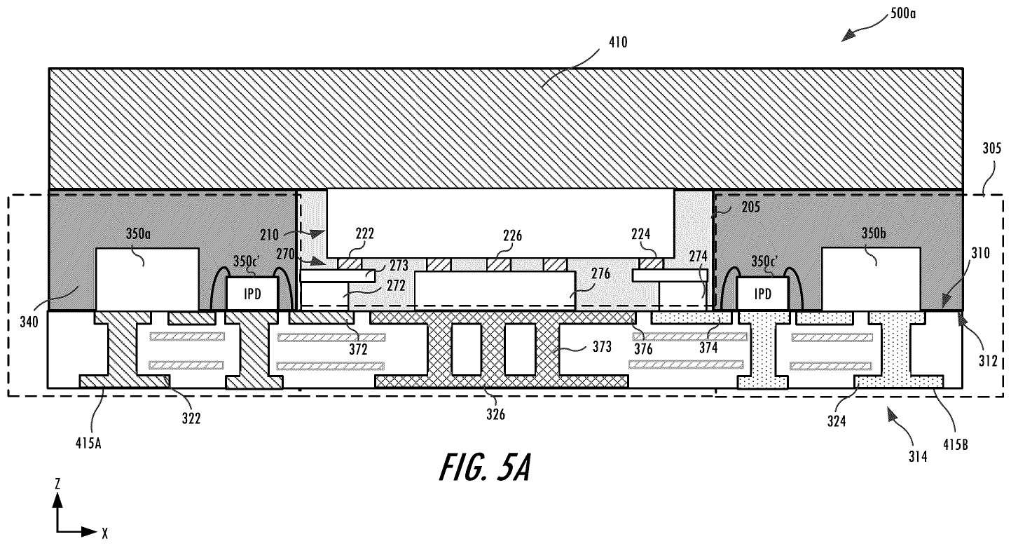

FIGS. 3A to 3F illustrate various examples of passive component assemblies 305a, 305b, 305c, 305d, 305e, and 305f (collectively 305) according to some embodiments of the present disclosure. As shown in FIGS. 3A to 3F, the passive component assemblies 305 respectively include an interconnect structure 310. The interconnect structure 310 includes internal conductive patterns 373 and one or more passive electrical components 350a, 350b, 350c/c′/c″ (collectively 350) on a first surface 312. In some embodiments, interconnect structure 310 may be formed as a multi-layer laminate, such as a printed circuit board (PCB) or redistribution layer (RDL) laminate structure, with the conductive patterns 373 implemented as conductive traces and/or vias within the substrate of the PCB or the RDL laminate structure.

The conductive patterns 373 may provide various routing and/or circuitry within the interconnect structure 310. For example, the conductive patterns 373 may electrically connect interconnection pads 372, 374, 376 on the first surface 312 of the interconnect structure 310 to one another and/or to interconnection pads 322, 324, 326 on a second surface 314 of the interconnect structure 310. In particular, as shown in FIGS. 3A to 3F, the interconnection pads 322, 324, 326 are configured to be coupled to the gate terminal 222, the drain terminal 224, and the source terminal 226 of a die 210 that is mounted on the second surface 314 opposite the passive component(s) 350. In some embodiments, the interconnection pads 372, 374, 376 may be configured to be coupled to the gate terminal 222, the drain terminal 224, and the source terminal 226 of a die 210 that is mounted on the first surface 312 adjacent the passive component(s) 350. More generally, the interconnection structure 310 may be configured to accept and provide electrical connections to one or more transistor dies 210 on the first surface 312 and/or on the second surface 314. Though illustrated by way of example as a single pads, one or more of the interconnection pads 322, 324, 326, 372, 374, 376 may be implemented by multiple pads.

The passive electrical components 350 may include, for example, resistors/transmission lines, capacitors, and/or inductors implemented by SMDs and/or IPDs and attached (e.g., by solder, conductive epoxy, etc.) and electrically connected to the conductive elements and/or traces provided by conductive connections 373. In the examples of FIGS. 3A to 3F the passive electrical components 350a are arranged for electrical connection to an input lead of a package, the passive electrical components 350b are arranged for electrical connection to an output lead of the package, and the passive electrical components 350c are arranged for electrical connection between the components 350a and 350b and one or more terminals 222, 224, 226 of the die 210. The passive electrical components 350 may be attached to respective interconnection pads 372, 374, 376 on the first surface 312 of the interconnect structure 310 in surface mount (e.g., 350c), wirebond (e.g., 350c′), or flip-chip (e.g., 350c″) configurations. In the flip-chip configuration, the passive electrical components 350c″ may include conductive pads that are aligned with and electrically coupled to one or more interconnection pads 372, 374, 376.

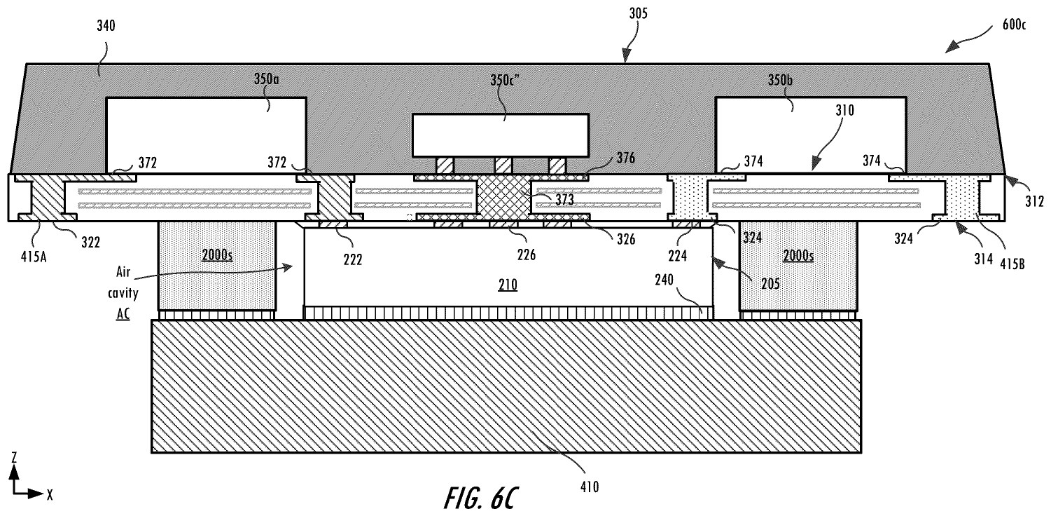

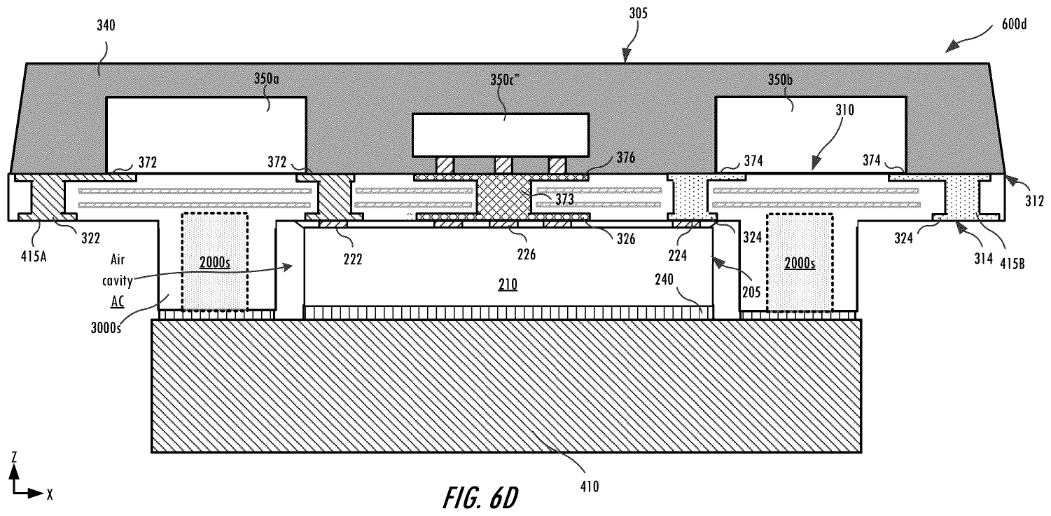

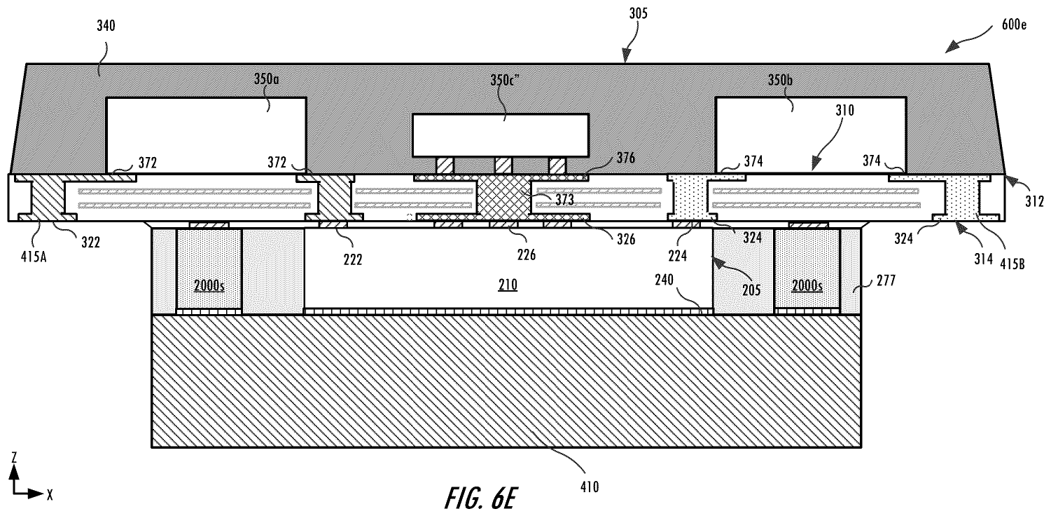

In the examples of FIGS. 3A to 3F, the passive electrical components 350 are preassembled on the interconnect structure 310 for modular assembly with any of the example active component assemblies 205. In some embodiments, as shown in FIGS. 3A, 3B, and 3C, the passive electrical components 350 are encased in a mold structure 340 (e.g., a dispensed and cured encapsulant) on the first surface 312. The mold structure 340 is separate or distinct from a package overmold material (e.g., 640; see FIG. 6B) that may be subsequently formed to encapsulate both the active and passive component assemblies 205 and 305 in a package as described herein. For example, the mold structure 340 may be formed of a harder or softer material than the package overmold material.

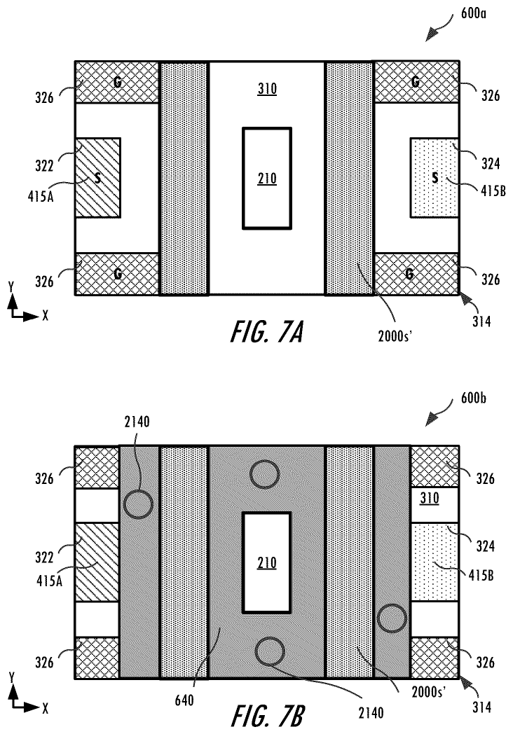

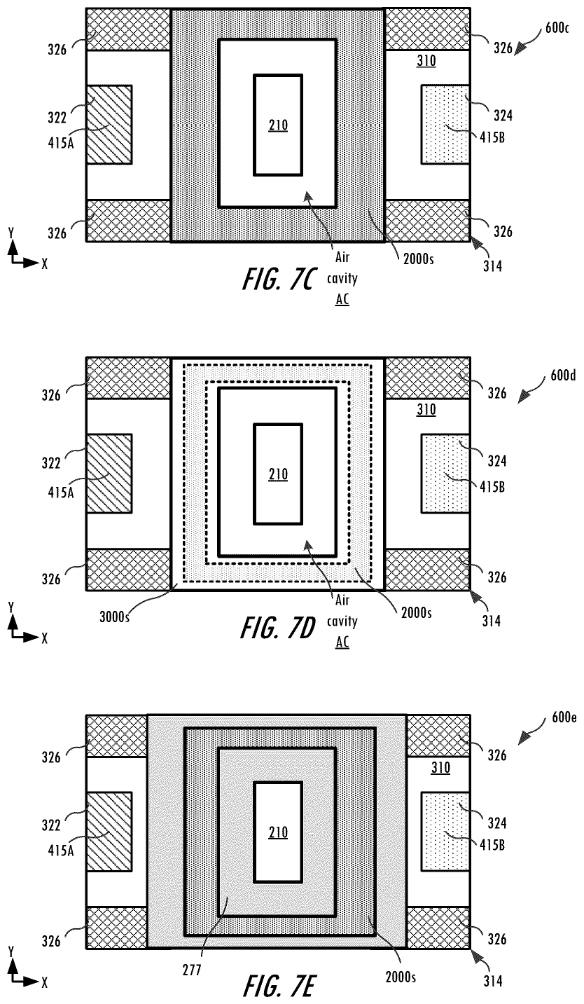

The mold structure 340 or other protective member may encapsulate or otherwise cover the passive electrical components 350, while leaving conductive contact pads exposed or otherwise free of the protective member. As shown in FIGS. 3A, 3B, and 3C, the mold structure 340 is not formed on the second surface 314 (i.e., the second surface is free of the mold structure 340) of the interconnect structure 310, such that the interconnection pads 322, 324, 326 on the second surface 314 are exposed by or otherwise outside of the mold structure 340. In other embodiments, the mold structure 340 may be omitted, as shown in FIGS. 3D, 3E, and 3F, such that the interconnection pads 372, 374, 376 on the first surface 312 and the interconnection pads 322, 324, 326 on the second surface 314 are exposed. As such, the passive modules 305 may be configured to allow electrical testing of the passive component(s) 350 via one or more exposed interconnection pads 322, 324, 326, 372, 374, and/or 376 prior to final assembly in a packaged device. In some embodiments, the exposed interconnection pads 322, 324, 326, 372, 374, and/or 376 may be arranged in a ground-signal-ground (G-S-G; see FIGS. 7A to 7E) layout in plan view, which may be used to facilitate testing (before packaging) and/or for electrical connections to the active module and/or to higher level systems or other external connections (after packaging).

The passive electrical components 350 coupled by the interconnect structure 310 may be configured to provide, for example, input matching circuits, output matching circuits, and/or harmonic termination circuits that are used to impedance match at the fundamental frequency and/or to terminate intermodulation products to ground. The use of passive component assemblies 305 described herein may thus provide greater flexibility in that different performance characteristics (e.g., to address harmonics at different frequencies, different impedances, etc.) for different applications may be achieved by swapping passive component assemblies 305 and/or the passive electrical components 350. In addition, the exposed interconnection pads 322, 324, 326, 372, 374, and/or 376 of the passive component assemblies 305 can be used for electrically testing before integration with the active component assemblies described herein, which may improve yield and reduce product costs. As such, passive component assemblies 305 in accordance with embodiments of the present disclosure may enable a modular approach for fabricating RF transistor amplifiers with desired performance characteristics.

Embodiments of the present disclosure may include various combinations of active component assemblies (e.g., 205a, 205b, 205c, 205d, 205e, 205f) and passive component assemblies (e.g., 305a, 305b, 305c, 305d, 305e, 305f), mounted on the first side 312 or second side 314 of the passive component assemblies. It will be understood that these embodiments are provided by way of illustration rather than limitation, and that any and all configurations of the passive component assembly 305 and active component assembly 205 are included in the scope of the present disclosure.

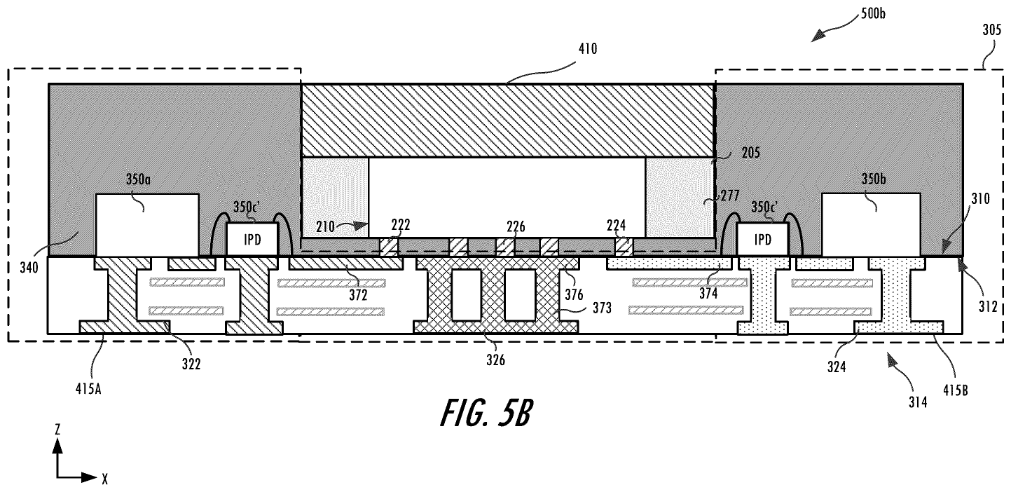

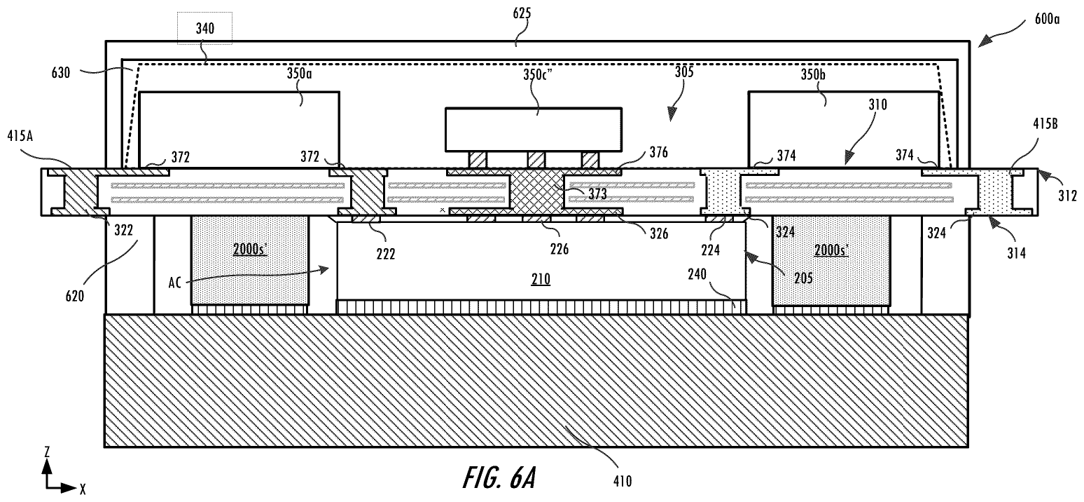

Likewise, the active component assemblies 205 and passive component assemblies 305 may be implemented in a packaged device using various packaging components that provide one or more protective structures. FIGS. 4A, 4B, 4C, 4D, and 4E are schematic diagrams illustrating various examples of packaging components for use with active component assemblies 205 and passive component assemblies 305 to provide packaged transistor devices according to some embodiments of the present disclosure. The packaging components include a carrier substrate 410 including an attachment surface or “flange” on which the assemblies 205 and 305 are mounted, and an electrically insulating protective member that seals and protects the assemblies 205 and 305 from moisture and dust particles. The protective member may include an encapsulant (e.g., a plastic over mold (OMP)) that encapsulates the active and/or passive components 210 and/or 350 of the assemblies 205 and 305, a lid member that is placed and attached over the active components 210 and/or the passive components 350 to define an open cavity that extends around the components 210 and/or 350, or combinations of encapsulating and open cavity structures.

The packaging components also include electrically conductive leads 415A, 415B (also referred to herein as package leads or RF leads) that are used for electrical connections to external circuit elements such as input and output RF transmission lines and bias voltage sources. The leads 415A, 415B may be coupled to the passive electrical components 350 of the passive module 305 using, for example, wire bonds or a conductive die attach material. In some embodiments, the leads 415A and 415B may be coupled to the interconnection pads on the first surface 312 of the interconnect structure 310 (e.g., to interconnection pads 372 and 374, respectively). In some embodiments, the leads 415A and 415B may be coupled to the interconnection pads on the second surface 314 (e.g., to interconnection pads 322 and 324, respectively). In some embodiments, the leads 415A, 415B may be directly coupled or may be integral to the interconnection pads, such that the use of wire bonds to connect the RF transistor amplifier 200 to leads 415A, 415B may be reduced or eliminated. Although primarily illustrated with reference to two leads 415A and 415B, embodiments of the present disclosure are not so limited. In some embodiments, three or more leads may be provided, for example, coupled to the interconnection pads 322 or 372 (e.g., as gate leads), 324 or 374 (e.g., as drain leads), and 326 or 376 (e.g., as source leads).

The passive electrical components 350 may thereby be electrically coupled between the gate terminal 222 and the first (e.g., input) lead 415A, and/or between the drain terminal 224 and the second (e.g., output) lead 415B. In particular, an RF signal input to the transistor die 210 on the input lead 415A may be passed through the interconnect structure 310 to passive electrical components 350 and from there to a gate terminal 222 of the transistor die 210, and the amplified output RF signal may be passed from the drain terminal 224 of the transistor die 210 to the passive electrical components 350 and from there through the interconnect structure 310 where the RF signal is output through output lead 415B.

In particular, FIG. 4A illustrates an open cavity packaging structure 400a including a carrier substrate 410, sidewall members 620, lid member 625, and conductive leads 415A, 415B. An active component assembly 205 may be provided on a surface 312, 314 of a passive component assembly 305, and may be mounted on a surface of the carrier substrate 410 internal to the packaging structure 400a. The sidewalls 620 and/or lid 625 may be formed of or include an insulating material in some embodiments. For example, the sidewalls 620 and/or lid 625 may be formed of or include ceramic and/or a PCB. In some embodiments, the sidewalls 620 and/or lid 625 may be formed of, for example, Al₂O₃. The lid 625 may be glued to the sidewalls 620 using an epoxy glue. The sidewalls 620 may be attached to the carrier substrate 410 via, for example, brazing. The sidewalls 620 may provide mechanical support for the leads 415A, 415B. The leads 415A, 415B may be electrically connected to exposed conductive pads 372, 374, 322, 324 of a passive component assembly 305 by wirebond connections. The leads 415A, 415B may be configured to extend through the sidewalls 620, though embodiments of the present disclosure are not limited thereto. The lid 625 seals an open air cavity around the component assemblies 205 and 305 and the connections thereto.

FIG. 4B illustrates a lead frame packaging structure 400b including a carrier substrate 410 and conductive leads 415A, 415B. As in FIG. 4B, an active component assembly 305 may be provided on a surface 312, 314 of a passive component assembly 205, and may be mounted on a surface of the carrier substrate 410. The leads 415A, 415B may likewise be electrically connected to conductive pads 372, 374, 322, 324 by wirebond connections. Rather than using a lid 625 and sidewalls 620 as a protective member, the packaging structure 400b includes a plastic or other non-conductive package encapsulant material 640, as shown by the packaging structure 400c of FIG. 4C. The encapsulant material 640 can be molded (e.g., by injection or transfer molding) directly on to the substrate 410 to form a solid structure that directly contacts and encapsulates the active components 210 and/or the passive components 350 and associated electrical connections as well as at least part of the substrate 410.

FIGS. 4D and 4E illustrate packaging structures 400d and 400e implemented as mechanical support structures 2000s and 2000s′, respectively. The mechanical support structure(s) 2000s, 2000s′ (also referred to herein as a standoff assembly 2000s) may extend along or adjacent one or more sides of the active component assembly 205.

In particular, FIG. 4D illustrates a packaging structures 400d implemented by a ring or frame structure 2000s that defines an air cavity that is sized to accept one or more transistor dies 210 or active component assemblies 205. FIG. 4E illustrates a packaging structures 400e implemented by one or more bar-shaped support structures 2000s′ which may be arranged adjacent to or more sides of the active component assembly 205. In some embodiments, the support structures 2000s, 2000s′ may have a thickness substantially similar to a thickness of the active component assembly 205, so as to be mounted on the carrier substrate 410 and provide improved mechanical support for the passive component assembly 305 stacked thereon.

Still referring to FIGS. 4D and 4E, in some embodiments the support structure(s) 2000s, 2000s′ may be formed of one or more materials that are configured for thermal compatibility (e.g., in terms of coefficient of thermal expansion (CTE)) with component(s) of the assemblies 205, 305 and/or for thermal conductivity (to improve heat extraction from the packages by conducting heat away from the assemblies 205, 305 and toward the substrate 410). For example, the support structure(s) 2000s, 2000s′ may be formed of copper, aluminum nitride, silicon carbide, or aluminum. In embodiments where the substrate 410 is also formed of a thermally conductive material, the support structure(s) 2000s, 2000s′ may be thermally coupled to the substrate (e.g., by a thermally conductive die attach layer, such as a eutectic layer, or other thermally conductive adhesive layer; generally denoted herein by 240), so as to provide an additional heat conduction path. In some embodiments, the support structure(s) 2000s, 2000s′ may provide a heat conduction path that is distinct or separate from an electrical ground path (e.g., as provided by the source terminal(s) 226 on the front surface of the transistor die 210).

The support structure(s) 2000s, 2000s′ may thus be configured to conduct heat away from the active component assembly 205 and/or the passive component assembly 305 and toward the thermally conductive substrate 410. The material(s) of the support structure(s) 2000s, 2000s′ may be electrically conductive in some embodiments, or electrically insulating in other embodiments. More generally, the shapes and/or material(s) of the support structure(s) 2000s, 2000s′ may be configured to provide a desired thermal conductivity and/or CTE.

The support structures 2000s and 2000s′ can be used alone or in combination with one or more of the packaging structures 400a, 400b, and/or 400c. For example, the ring- or frame-shaped support structure 2000s may be sized and dimensioned such that, when the transistor die 210 is provided on the substrate 410 within the perimeter of the support structure 2000s, an air cavity extends around the transistor die 210. In some embodiments, a passive module 305 (e.g., with passive components 350 encapsulated by a mold structure 340) may be stacked on the support structure 2000s opposite the substrate 410 with the exposed interconnection pads 322, 324, 372, and/or 374 providing the input or output package leads 415A or 415B. As such, some packages may include characteristics of both molded and open-cavity packages, as further described by way of example with reference to the embodiments of FIGS. 6C and 6D.

Embodiments of the present disclosure may include various combinations of active component assemblies 205, passive component assemblies 305, and packaging components (e.g., 400a, 400b, 400c, 400d, 400e; collectively 400), and are not limited to those specifically shown and described herein. In some embodiments, the passive component assembly 305 may include the active component assembly 205 or transistor die 210 on the same side or surface of the interconnect structure as the passive electrical components 350, which may be referred to herein as an active module on same side of passive module (AMSPM) configuration. In some embodiments, the passive component assembly 305 may include the active component assembly 205 or transistor die 210 on an opposite surface of the interconnect structure than the passive electrical components 350, which may be referred to herein as an active module on backside of passive module (AMBPM) configuration.

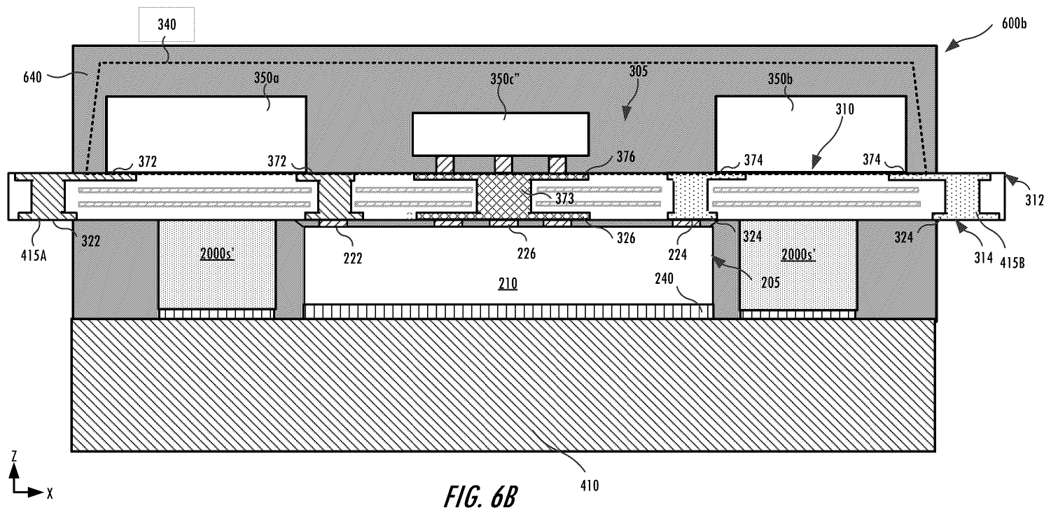

FIGS. 5A and 5B are schematic cross-sectional views illustrating various examples of packaged power transistor devices including active and passive component assemblies on the same surface according to some embodiments of the present disclosure. In particular, FIGS. 5A and 5B illustrate example packages 500a and 500b including an active component assembly 205 coupled to a passive component assembly 305 in an AMSPM configuration, where the die 210 is on a surface 312 of the interconnect structure 310 adjacent one or more passive electrical components 350 on the same surface 312.

As shown in FIG. 5A, the packaged power transistor device 500a includes an active component assembly 205 (shown by way of example as the active component assembly 205b of FIG. 2B) on a first surface 312 of a passive component assembly 305, in combination with packaging components 400 including a carrier substrate 410 and a mold structure or encapsulant 340. Interconnection pads 372, 374, and 376 on the first surface 312 of the interconnect structure 310 are electrically coupled to the gate connection pad 272, the drain connection pad 274, and the source connection pad 276 of the coupling element 270, respectively (and thus, are electrically coupled to the gate terminal 222, drain terminal 224, and source terminal 226 of the die 210, respectively). The passive electrical components 350 are attached to interconnection pads 372, 374, 376 on the surface 312 of the interconnect structure 310, in surface mount (e.g., 350a, 350b), wirebond (e.g., 350c′), and/or flip-chip configurations, and the active component assembly 205 is attached to the surface 312 adjacent to the passive electrical components 350.

In the example AMSPM configuration of FIG. 5A, the active component assembly 205 and passive component assembly 305 may be at least partially encased in a mold structure 340, for example, after assembling the active component assembly 205 and the passive component assembly on the substrate 410. The mold structure 340 may be formed of a plastic or a plastic polymer compound, which may be injection molded around the active component assembly 205 and/or the passive component assembly 305, thereby providing protection from the outside environment.

As shown in FIG. 5B, the packaged power transistor device 500b includes an active component assembly 205 (shown by way of example as the active component assembly 205f of FIG. 2F) on a first surface 312 of a passive component assembly 305, similar to the device 500a of FIG. 5A. The device 500b further includes the mold structure or encapsulant 340 as a packaging component 400, with the substrate 410 included in the active component assembly 205. For example, the active component assembly 205 including the substrate 410 may be flip chip mounted on the first surface 312 adjacent to the passive electrical components 350 (which are attached to interconnection pads 372, 374, 376, in surface mount 350a, 350b, wirebond 350c′, and/or flip-chip configurations), and the active component assembly 205 and passive component assembly 305 may be at least partially encased in the overmold 340. As another example, the passive electrical components 350 may be assembled on the first surface 312 of the interconnection structure and encapsulated in a mold structure 340 that exposes the interconnection pads 376, such that the active component assembly 205 including the substrate 410 may be flip chip mounted on the first surface 312 after the overmold 340 is formed.

In FIGS. 5A and 5B, the second surface 314 of the interconnect structure 310 is free of the mold structure 340, and the conductive leads 415A and 415B are integrated on the second surface 314 (in particular, coupled to or integrated with the exposed interconnection pads 322 and 324, respectively) of the interconnect structure 310 opposite the die 210 to provide input RF signals to the die (e.g., to the gate terminal 222 via passive components 350a, 350c′) and to provide amplified output RF signals from the die 210 (e.g., from the drain terminal 224 via passive components 350c′, 350b). However, it will be understood that the leads 415A, 415B may be provided on the same surface as the die 210 (e.g., on the first surface 312 of the interconnect structure 310 and protruding from the mold structure 340) in some embodiments.

FIGS. 6A, 6B, 6C, 6D, and 6E are schematic cross-sectional views illustrating various examples of packaged power transistor devices including active and passive component assemblies on the opposite surfaces according to some embodiments of the present disclosure. FIGS. 7A, 7B, 7C, 7D, and 7E are bottom plan views illustrating the packaged power transistor devices of FIGS. 6A, 6B, 6C, 6D, and 6E, respectively, with the carrier substrate removed. In particular, FIGS. 6A to 7E illustrate example packages 600a to 600e including an active component assembly 205 coupled to a passive component assembly 305 in an AMBPM configuration, where the die 210 is on a surface 314 of the interconnect structure 310 opposite the surface 312 having the one or more passive electrical components 350 thereon, in various combinations with packaging components 400 including a carrier substrate 410, support structures 2000s, 2000s′, a mold structure or encapsulant 340, and/or lid 625 and sidewall structures 620.

In FIGS. 6A to 6E, an active component assembly 205 (shown by way of example with reference to active component assembly 205a or 205d) is provided on the second or back surface 314 of the passive component assembly 305 (shown by way of example with reference to passive component assembly 305c or 305f) such that interconnection pads 322, 324, and 326 on the second surface 314 of the interconnect structure 310 are electrically coupled to the gate terminal 222, drain terminal 224, and source terminal 226 of the die 210, respectively. In particular, the transistor die 210 is flip chip mounted on the surface 314 of the interconnect structure 310, with the conductive pillars 222, 224, and 226 (defining the gate, drain, and source terminals) directly coupled to the interconnection pads 322, 324, and 326, respectively. An underfill material may be provided around the pillars 222, 224, and 226 in some embodiments. The passive electrical components 350 are attached to respective interconnection pads 372, 374, 376 on the opposite surface 312 of the interconnect structure 310, in surface mount (e.g., 350a, 350b), wirebond (e.g., 350c′), and/or flip-chip configurations, in some instances with a mold structure or encapsulant 340 on the first surface 312 of the interconnect structure 310. As shown in the bottom plan views of FIGS. 7A to 7E, the exposed interconnection pads 322, 324, 326 may be configured in a ground-signal-ground (G-S-G) arrangement or layout, for example, to facilitate electrical testing (e.g., before packaging) and/or flip chip connections to the terminals 222, 224, 226 of the active module 205.

In the example AMBPM packages 600a to 600e of FIGS. 6A to 6E, the carrier substrate 410 may be thermally conductive substrate 410 (e.g., a metal slug, leadframe, or flange) that is mounted (e.g., using a thermal layer 240) on a surface of the active component assembly 205 opposite the passive component assembly 305 for improved thermal dissipation of the heat generated by the components of the active and/or passive component assemblies 205 and/or 305. In some embodiments, the thermal layer 240 may be omitted.

The packages 600a to 600e further includes one or more support structures 2000s, 2000s′ on the second surface 314 of the interconnect structure 310 adjacent the die(s) 210. The support structure(s) 2000s, 2000s′ extend between the thermally conductive substrate 410 and the second surface 314 of the interconnect structure 310. The support structure(s) 2000s, 2000s′ may extend along or adjacent one or more sides of the die 210, and in some embodiments define an air gap or air cavity AC that extends along one or more sides (or completely around) the die 210. The support structure(s) 2000s, 2000s′ may be mounted (e.g., using a thermal layer 240) on a surface of the thermally conductive substrate 410 to provide improved mechanical support for the passive component assembly 305 stacked thereon, and may have a thickness (e.g., in the Z-direction) greater than or equal to a thickness of the active component assembly 205. The thickness of the support structure(s) 2000s, 2000s′ may be substantially similar to the die(s) 210 in some embodiments. In some embodiments, the support structure(s) 2000s may be formed of one or more materials that may improve thermal conduction, e.g., to provide an additional thermal path to conduct heat away from the active component assembly 205 and/or the passive component assembly 305 and toward the thermally conductive substrate 410.

FIG. 6A illustrates an example of a packaged power transistor device 600a that includes the substrate 410, sidewalls 620, and lid 625. The substrate 410, sidewalls 620, and lid 625 may define an internal open cavity 630. The active component assembly 205 and the passive component assembly 305 are disposed inside the internal cavity 630, and may be enclosed in and protected by the sidewalls 620 and the lid 625. In some embodiments, the passive component assembly 305 may include the passive electrical components 350 pre-assembled in a mold structure 340 on the first surface 312 of the interconnect structure 310.

As shown in FIGS. 6A and 7A, the support structures are provided as bar-shaped standoff structures 2000s′ that extend along respective sides of the transistor die 210 on the second surface 314 and define an air gap or air cavity AC therebetween. Although illustrated with reference to two support structures 2000s′, fewer or more support structures may be included. For example, in some embodiments a single frame-shaped support structure 2000s may be used in place of the two support structures 2000s′. Similarly, while illustrated as extending in the Y-direction (in length) and the Z-direction (in thickness/height) by way of example, the support structure(s) 2000s′ may be implemented as extending in the X-direction (in length) and the Z-direction (in thickness/height) in other embodiments. The support structures 2000s′ and the sidewalls 620 may provide mechanical support for the interconnect structure 310 including the leads 415A, 415B, which are integrated with or otherwise electrically connected to the exposed interconnection pads 372, 374 or 322, 324.

FIG. 6B illustrates an example of a packaged power transistor device 600b similar to the package 600a of FIG. 6A, including the support structure 2000s′ on the second surface 314 of the interconnect structure adjacent the die 210. Rather than a lid 625 and sidewalls 620 for protection and mechanical support, a package overmold or encapsulant material 640 is formed on both surfaces 312 and 314 of the interconnect structure 310. The package encapsulant material 640 surrounds or encapsulates the passive components 350 on the first surface 312, and the active components 210 and the support structure 2000s′ on the second surface 314. That is, the active component assembly 205 and the passive component assembly 305 are enclosed in and protected by the package encapsulant material 640. In some embodiments, the passive component assembly 305 may include the passive electrical components 350 pre-assembled in a mold structure 340 (which may differ from the package encapsulant material 640) on the first surface 312.

As shown in FIGS. 6B and 7B, the support structures are provided as bar-shaped standoff structures 2000s′ that extend along respective sides of the transistor die 210 on the second surface 314, with portions of the package encapsulant material 640 therebetween. As noted above, fewer (e.g., a single ring/frame structure 2000s) or more support structures, extending in the same or different directions than those shown, may be provided in the package 600b. In some embodiments, the second surface 314 of the interconnect structure 310 may include one or more holes or openings 2140, which may act as mold-lock features. The package encapsulant material 640 may extend into or may otherwise be provided in the opening(s) 2140, which may enhance adhesion. The support structures 2000s′ and the portions of the package encapsulant material 640 on the second surface 314 may provide mechanical support for the interconnect structure 310 including the leads 415A, 415B integrated with or otherwise electrically connected to the interconnection pads 372, 374 or 322, 324, which are exposed or otherwise provided outside of the package overmold material 640.

FIGS. 6C, 6D, and 6E illustrates further examples of packaged power transistor devices 600c, 600d, and 600e that include support structures 2000s, 2000s′ on the second surface 314 of the interconnect structure 310 adjacent the die 210. The packaged power transistor device 600c, 600d, and 600e may include the component assemblies 205 and 305 in a stacked (e.g., in the Z-direction) configuration similar to the packages 600a and 600b of FIGS. 6A and 6B, but may utilize structures that are part of or integral to the respective component assemblies 205 and 305 as protective members for environmental protection, such that one or more packaging components 620, 625, 640 may be omitted.

In particular, in the example package 600c of FIGS. 6C and 7C, the support structure 2000s has a ring or frame shape (also referred to herein as a frame structure 2000s) that defines an air gap or air cavity AC extending along or around respective sides of the transistor die 210. The support structure 2000s may be sized to correspond to one or more dimensions of the substrate 410 to which the support structure 2000s is mounted (e.g., by thermal layer 240). As such, the support structure 2000s and the substrate 410 collectively define a protective member around the transistor die 210 on the second surface 314 of the interconnect structure 310. That is, the transistor die 210 on the second surface 314 of the interconnect structure 310 is disposed inside an internal air cavity defined by the frame structure 2000s and the substrate 410. As noted above, the support structure 2000s may be formed of a thermally conductive material (e.g., copper, aluminum nitride, silicon carbide, or aluminum), so as to provide a heat conduction path (e.g., extending around the transistor die 210) between the substrate 410 and the passive component assembly 350, which is at least partially separate from the heat conduction path between the die 210 and the substrate 410. Also, while illustrated as separate components, the substrate 410 and the support structure 2000s may be manufactured as a single or unitary structure (e.g., in embodiments where the substrate 410 and the support structure 2000s are formed of the same material).

As shown in FIG. 6C, the passive component assembly 305 includes the passive electrical components 350 pre-assembled in a mold structure 340 on the first surface 312 of the interconnect structure 310, such that the mold structure 340 defines a protective member on the passive electrical components 350. The second surface 314 of the interconnect structure 310 is free of the mold structure 340, such that conductive pads 322, 324, 326 on the second surface 314 are exposed by or otherwise outside of the mold structure (e.g., in a G-S-G layout or arrangement). In some embodiments, one or more conductive pads 372, 374, 376 may also be exposed by or otherwise outside of the mold structure 340. One or more of the exposed conductive pads 322, 324, 326, 372, 374, 376 are electrically coupled to the passive electrical components 350 (e.g., directly or by internal conductive patterns 373. The exposed conductive pads 322, 324, 326, 372, 374, 376 may thereby be used to provide electrical connections to the gate 222, source 226, and/or drain terminals 224 of the transistor die 210 during package assembly, and/or to electrically test one or more of the passive electrical components 350 (e.g., prior to package assembly).

As such, the package 600c includes a combination of a mold structure 340 on the passive electrical components 350, and a frame structure 2000s that provides an air cavity AC that extends around the transistor die 210. In other words, the package 600c includes features of both overmold and open cavity packages. In some embodiments, the support structure 2000s and the die 210 may be pre-assembled on the substrate 410 (for example, mounted by thermal layer(s) 240, such as the module 205e of FIG. 2E), such that the pre-assembled passive component assembly 305 can be subsequently stacked thereon (e.g., in the Z-direction) to complete the package 600c without additional packaging components 400.

The example package 600d of FIGS. 6D and 7D illustrates an embodiment in which a support structure 3000s is integral to or is otherwise defined by a portion of the interconnect structure 310 of the passive component assembly 305. The support structure 3000s may similarly have a ring or frame shape that provides an air cavity AC extending around the transistor die 210. For example, the support structure 3000s may be integral to and protrude from the surface 314 of the interconnect structure 310 to define the cavity AC. As the integral support structure 3000s may be formed of a same material as the interconnect structure 310 (e.g., a PCB or laminate), the support structure 3000s may not be configured for heat conduction in some embodiments. In other embodiments, the support structure 3000s may include the thermally conductive support structure 2000s or 2000s′ embedded or otherwise within, so as to provide a heat conduction path similar to that of the package 600c. The support structure 3000s may likewise be sized to correspond to one or more dimensions of the substrate 410 to be mounted thereon so as to collectively define a protective member around the transistor die 210 on the second surface 314 of the interconnect structure 310.

As shown in FIG. 6D, the passive component assembly 305 includes the passive electrical components 350 pre-assembled in a mold structure 340 on the first surface 312 of the interconnect structure 310, such that the mold structure 340 defines a protective member on the passive electrical components 350 on the first surface 312 and provides exposed contact pads 322, 324, 326 on the second surface 314 for electrical connection and/or testing, similar to that of the package 600c. Because the support structure 3000s is provided by an integral portion of the interconnect structure 310, package assembly may differ from the package 600c in that the active module 205 (including the die 210 and the substrate or flange 410, such as the module 205c of FIG. 2C) may be stacked on the second surface 314 of passive module 305 such that the transistor die 210 is disposed inside the internal air cavity defined by the frame structure 3000s and the substrate 410. That is, the support structure 3000s may be part of the passive module 305 in some embodiments, and the active module 205 may be stacked or assembled to provide the die 210 within the internal air cavity AC defined by the support structure 3000s to complete the package 600d without additional packaging components 400.

The example package 600e of FIGS. 6E and 7E illustrates another embodiment in which the support structure 2000s is included in the active module 205 (such as the module 205d of FIG. 2D). The support structure 2000s may similarly have a ring or frame shape that provides an cavity extending around the transistor die 210, and may be formed of a thermally conductive material so as to provide a heat conduction path similar to that of the package 600c. However, the encapsulant material 277 fills the space or cavity defined between the frame structure 2000s and the die 210. The support structure 2000s and surrounding encapsulant 277 may be sized to correspond to one or more dimensions of the substrate 410 to be mounted thereon so as to collectively define a protective member around the transistor die 210 on the second surface 314 of the interconnect structure 310.

As shown in FIG. 6E, the passive component assembly 305 includes the passive electrical components 350 pre-assembled in a mold structure 340 on the first surface 312 of the interconnect structure 310, such that the mold structure 340 defines a protective member on the passive electrical components 350 on the first surface 312 and provides exposed contact pads 322, 324, 326 on the second surface 314 for electrical connection and/or testing, similar to that of the package 600c. The active module 205 including the die 210, the support structure 2000s, and surrounding encapsulant 277 on the substrate or flange 410 may thereby be stacked on the second surface 314 of the passive module 305 to complete the package 600e without additional packaging components 400.

The packages 600a to 600e including modular active and passive component assemblies 205 and 305 according to some embodiments of the present disclosure thus each include a transistor die 210 having a gate terminal 222, a drain terminal 224, and a source terminal 226, one or more passive electrical components 350 electrically coupled to the gate terminal 222, the drain terminal 224, and/or the source terminal 226, and a support structure 2000s, 2000s′ on the surface 314 of the passive module 305 that defines or otherwise provides a cavity (which may be an air cavity or filled with an encapsulant) extending along one or more sides of the transistor die 210. The packages 600c to 600e may further include characteristics of overmold and open cavity packages.

In addition, in the packages 600a to 600e, the substrate 410 may be a thermally conductive material that provides a first heat conduction path (e.g., between the transistor die 210 and the substrate 410). The support structures 2000s, 2000s′ are coupled to the substrate 410 (e.g., by a thermal layer 240) to provide a second heat conduction path (e.g., between the passive component assembly 305 or die 210 and the substrate 410).

Moreover, the packages 500a, 500b, and 600a to 600e may include one or more conductive pads 322, 324 that are coupled to the one or more passive electrical components 350 and are exposed by the mold structure 340 and configured to be tested prior to assembly of the transistor die 210 on the passive component assembly 305. The package configurations described herein are provided by way of example only, and may include variations and any and all combinations the active component assemblies and passive component assemblies described herein, in AMSPM or AMBPM configurations.

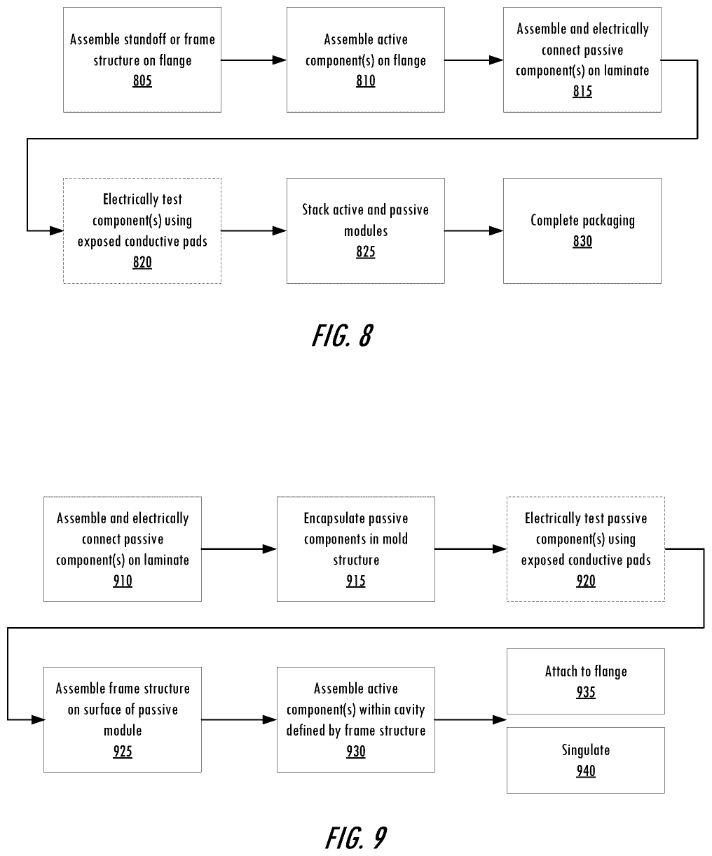

FIG. 8 is a flowchart diagram illustrating example operations for fabricating packaged power transistor devices including modular active and passive component assemblies according to some embodiments of the present disclosure. As shown in FIG. 8, a support structure (e.g., a standoff structure 2000s′ or a frame structure 2000s) is assembled on a surface of a carrier substrate (e.g., a thermally conductive substrate 410) at block 805. The substrate 410 may be thermal management structure, such as a metal flange or heatsink. For example, the substrate 410 may be a single or multilayer copper/molybdenum/copper metal flange that comprises a core molybdenum layer with copper cladding layers on either major surface thereof.

At block 810, one or more active electrical components (e.g., transistor die(s) 210) are assembled on the surface of the substrate adjacent to the support structure, such that the support structure extends along one or more sides of the active electrical component(s). In some embodiments, the support structure may define a cavity that extends around the active electrical component(s). The active electrical component(s) and/or support structure(s) may be mounted on the substrate by a thermal adhesive or other thermally conductive layer (e.g., layer 240). The operations of blocks 805 and 810 may be performed in any order to define an active component assembly (e.g., active module 205).

Still referring to FIG. 8, one or more passive electrical components (e.g., 350) are assembled and electrically connected on an interconnect structure (e.g., a single- or multi-layer laminate 310) at block 815. The passive electrical component(s) may include SMDs and/or IPDs that are attached (e.g., by solder, conductive epoxy, etc.) and electrically connected to the conductive elements and/or traces of the interconnect structure. In some embodiments, an encapsulating structure (e.g., mold structure 340) is formed on the passive electrical component(s). The interconnect structure also includes one or more exposed conductive pads (e.g., conductive pads 322, 324, 326, 372, 374, 376) that are electrically coupled to the passive electrical component(s). The operations of blocks 815 may be performed in any order to define a passive component assembly (e.g., passive module 305).

Optionally, at block 820, electrical testing may be performed on the active and/or passive modules. For example, the passive electrical components of the passive module may be electrically tested using the exposed conductive pads. Defective component(s) may thereby be identified and replaced (either at the component-level or at the module level) before assembly into a final package, thereby improving yield. In embodiments where the passive modules include an encapsulating structure (e.g., mold structure 340) on the passive electrical component(s), the electrical testing at block 820 may be performed before or after forming the encapsulating structure.

At block 825, the passive module and the active module are stacked or otherwise assembled such that one or more of the passive electrical components are electrically coupled to the gate terminal, the drain terminal, and/or the source terminal of the transistor die(s). For example, the active module may be mounted (e.g., using one or more die attach layers) on the same or front surface of the passive module adjacent the passive electrical components (i.e., in an AMSPM configuration), or on an opposite or back surface of the passive module (i.e., in an AMBPM configuration). The active module may be mounted on the passive module in a flip chip configuration, with the gate drain, and/or source terminals facing the exposed conductive pads or other electrical interconnections of the passive module.

The package including the active and passive modules is completed at block 830, for example, by providing one or more additional packaging components for protection (e.g., a lid or package encapsulant material) and/or external connections (e.g., input and output leads 415A and 415B). For example, in some embodiments, a lid 625 and/or sidewall members 620 may be assembled on the stacked active and passive modules to arrive at the package 600a of FIG. 6A. In some embodiments, a package encapsulant material 640 may be formed around the passive components and the active components to arrive at the package 600b of FIG. 6B. In embodiments where the passive module is formed at block 815 with an encapsulating structure (e.g., mold structure 340) on the passive electrical component(s) and the active module is formed at blocks 805 and 810 with a protective member (e.g., the frame structure 2000s and the substrate 410), no additional packaging components may be required to arrive at the packages 600c to 600e of FIGS. 6C to 6E.

FIG. 9 is a flowchart diagram illustrating example operations for fabricating packaged power transistor devices including modular active and passive component assemblies according to some embodiments of the present disclosure. As shown in FIG. 9, one or more passive electrical components (e.g., 350) are assembled and electrically connected (e.g., via conductive connections 373 and/or conductive pads 372, 374, 376) on a surface of an interconnect structure (e.g., a single- or multi-layer laminate 310) at block 910. An encapsulating structure (e.g., mold structure 340) is formed on the passive electrical component(s) on the surface of the interconnect structure at block 915 to define a passive component assembly (e.g., passive module 305) in which one or more conductive pads (e.g., conductive pads 322, 324, 326) are exposed. Optionally, at block 920, the passive electrical components of the passive module may be electrically tested using the conductive pads. The electrical testing operations of block 920 may be performed before or after the encapsulation operations of block 915, such that defective passive electrical component(s) can be identified and replaced (either at the component-level or at the module level) before assembly into a final package, thereby improving yield.

Still referring to FIG. 9, a frame structure (e.g., frame structure 2000s) is assembled on a surface of the passive module at block 925. One or more active electrical components (e.g., transistor die(s) 210) are assembled on the surface of the passive module within the frame structure at block 930, such that the frame structure provides a cavity that extends around respective sides of the active electrical component(s). The cavity may be an open or air cavity in which one or more surfaces of the active component(s) do not physically contact another element.

At block 935, a carrier substrate or flange (e.g., a thermally conductive substrate 410) is attached to the active electrical component(s) and the frame structure to define an active component assembly (e.g., active module 205), and a dicing or other singulation operation is performed at block 940. The flange may be thermal management structure, such as a metal flange or heatsink, to which the active electrical component(s) and/or the frame structure are mounted by a thermal adhesive or other thermally conductive layer (e.g., layer 240). In some embodiments, the flange attachment operations at block 935 may be performed before the singulation operations at block 940, such that the singulation operations separate the flange into respective carrier substrates. In some embodiments, the singulation operations at block 940 may be performed before respective flange attachment operations at block 935. The resulting packaged transistor device may thus include features of both overmold and open cavity packages, such as the package 600c of FIG. 6C.

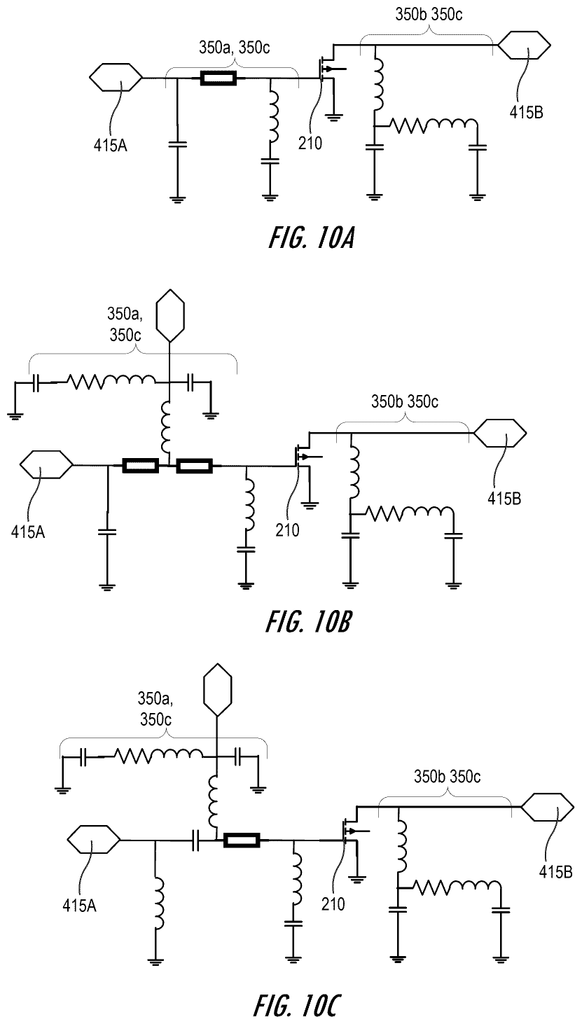

FIGS. 10A, 10B, and 10C are schematic circuit diagrams illustrating various circuit topologies that may be implemented by combinations of active and passive component assemblies according to some embodiments of the present disclosure. For example, the circuit elements 350a, 350c may be configured to provide input matching capabilities. Due to coupling between the gate lead 415A and the RF transistor amplifier die 210, the circuit elements 350a, 350c may be capable of affecting and/or conditioning a signal provided to the gates of the transistor die 210. Similarly, the circuit element 350b, 350c may be configured to provide output matching capabilities. Due to coupling between the drain lead 415B and the transistor die 210, the circuit elements 350b, 350c may be capable of affecting and/or conditioning a signal provided from the drains of the RF transistor amplifier die 210.

Modular passive component assemblies 305 as described herein can allow for ease of assembly of RF transistor amplifier packages with different characteristics and/or additional functionality, such as impedance matching and/or harmonic termination. For example, by providing passive component assemblies 305 including interconnect structures 310 with exposed interconnection pads, one or more of the passive electrical components 350a, 350b, 350c can be configured and/or replaced to provide application-specific impedance characteristics. That is, transistor packages may be designed and/or reconfigured to provide different input/output matching and/or harmonic termination characteristics using the same interconnect structure 310 populated with different arrangements and/or combinations of the passive electronic components 350 on the exposed interconnection pads 322, 324, 326, 372, 374, 376.

Thus, different functionality and/or capability may be coupled to a transistor die 205 of an active component assembly 205 simply by using a different passive component assembly 305 and/or differently populating the passive component assembly 305 with different combinations and/or arrangements of passive electrical components 350. In addition, as discussed above, modular passive component assemblies 305 including interconnection pads 322, 324, 326, 372, 374, 376 that are exposed outside of a mold structure 340 can allow for electrical testing and/or component/module replacement before final assembly into a package, thus improving yield.

Further advantages of modular passive and active component assemblies as described herein may include simplified device packaging in which a molded passive component can be stacked (e.g., in z-direction) on an active component surrounded by an air cavity, with package leads integrated on a surface of the passive component, thereby reducing and/or eliminating additional packaging components and associated fabrication complexity and cost. The stacked active and passive component assemblies may also provide improved thermal capabilities, with a first heat conduction path provided by a flange mounted to the backside of the transistor die (which may be separate from the electrical ground path to which the source terminals are coupled), and an additional heat conduction path provided by a thermally conductive support structure(s) coupled to the flange adjacent a periphery of the transistor die.

Some embodiments of the present disclosure may be used in high power RF transistors for cellular or aerospace and defense (A&D) applications, such as 20 W or higher average output power RF transistors for 5G base station application at 3.5 GHz and above. Embodiments of the present disclosure may also provide lower cost products at higher frequencies.

While embodiments of the present disclosure have been described herein with reference to particular HEMT structures, the present disclosure should not be construed as limited to such structures, and may be applied to formation of many different transistor structures, such as pHEMTs (including GaAs/AlGaAs pHEMTs) and/or GaN MESFETs.

Various embodiments have been described herein with reference to the accompanying drawings in which example embodiments are shown. These embodiments may, however, be embodied in different forms and should not be construed as limited to the embodiments set forth herein. Rather, these embodiments are provided so that this disclosure is thorough and complete and fully conveys the inventive concept to those skilled in the art. Various modifications to the example embodiments and the generic principles and features described herein will be readily apparent. In the drawings, the sizes and relative sizes of layers and regions are not shown to scale, and in some instances may be exaggerated for clarity.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises,” “comprising,” “includes,” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on,” “attached,” or extending “onto” another element, it can be directly on the other element or intervening elements may also be present. In contrast, when an element is referred to as being “directly on” or “directly attached” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Elements illustrated by dotted lines may be optional in the embodiments illustrated.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

In the drawings and specification, there have been disclosed typical embodiments of the invention and, although specific terms are employed, they are used in a generic and descriptive sense only and not for purposes of limitation, the scope of the invention being set forth in the following claims.

1. A transistor device package, comprising:
a transistor die comprising a gate terminal, a drain terminal, and a source terminal;
a passive component assembly including the transistor die on a surface thereof and comprising one or more passive electrical components electrically coupled to the gate terminal, the drain terminal, and/or the source terminal; and
a thermally conductive support structure on the surface of the passive component assembly and extending along one or more sides of the transistor die.

2. The transistor device package of claim 1, wherein the thermally conductive support structure provides a cavity that extends around the transistor die.

3. The transistor device package of claim 1, wherein a first surface of the transistor die is on the surface of the passive component assembly, and further comprising:
a substrate on a second surface of the transistor die opposite the first surface,
wherein the thermally conductive support structure extends between the substrate and the passive component assembly.

4. The transistor device package of claim 3, wherein the substrate comprises a thermally conductive material, wherein the thermally conductive structure provides a first heat conduction path, and the second surface of the transistor die provides a second heat conduction path.

5. The transistor device package of claim 1, wherein the surface of the passive component assembly including the transistor die thereon is a second surface, wherein the one or more passive electrical components are on a first surface of the passive component assembly opposite the second surface, and wherein the passive component assembly comprises conductive traces and/or vias that electrically couple the one or more passive electrical components on the first surface thereof to the gate terminal, the drain terminal, and/or the source terminal of the transistor die on the second surface thereof.

6. The transistor device package of claim 5, wherein the passive component assembly further comprises a mold structure on the one or more passive electrical components on the first surface thereof, and one or more conductive pads that are exposed by the mold structure.

7. The transistor device package of claim 6, wherein the second surface of the passive component assembly is free of the mold structure.

8. The transistor device package of claim 5, wherein the passive component assembly further comprises first and second package leads on the first or second surface, and wherein the one or more passive electrical components are electrically coupled between the gate terminal and the first package lead or between the drain terminal and the second package lead.

9. The transistor device package of claim 1, wherein the thermally conductive support structure comprises an electrically insulating material.

10. The transistor device package of claim 1, wherein the thermally conductive support structure comprises copper, aluminum, and/or silicon carbide.

11. The transistor device package of claim 1, wherein the one or more passive electrical components comprise a surface mount device and/or an integrated passive device.

12. The transistor device package of claim 1, wherein the gate terminal, the drain terminal, and the source terminal comprise conductive pillar structures adjacent the surface of the passive component assembly and electrically coupled to the one or more passive electrical components by conductive bumps.

13. The transistor device package of claim 1, wherein the surface of the passive component assembly comprises an integral support structure that provides a cavity extending around the transistor die, and the thermally conductive support structure is within the integral support structure.

14. A transistor device package, comprising:
a transistor die comprising a gate terminal, a drain terminal, and a source terminal; and
a passive component assembly comprising one or more passive electrical components electrically coupled to the gate terminal, the drain terminal, and/or the source terminal,
wherein the transistor die is on a surface of the passive component assembly, and the surface of the passive component assembly comprises a support structure that provides a cavity extending around the transistor die.

15. The transistor device package of claim 14, wherein the support structure comprises an electrically insulating material.

16. The transistor device package of claim 15, wherein the support structure comprises an integral portion of the passive component assembly that protrudes from the surface.

17.-21. (canceled)

22. A transistor device package, comprising:
an active component assembly comprising a transistor die having a gate terminal, a drain terminal, and a source terminal;
a passive component assembly including the active component assembly on a surface thereof and comprising one or more passive electrical components electrically coupled to the gate terminal, the drain terminal, and/or the source terminal;
a mold structure on the one or more passive electrical components; and
a frame structure providing a cavity that extends around the transistor die.

23. The transistor device package of claim 22, wherein a first surface of the transistor die is on the surface of the passive component assembly, and further comprising:
a substrate on a second surface of the transistor die opposite the first surface,
wherein the frame structure extends between the substrate and the passive component assembly.

24. The transistor device package of claim 23, wherein the cavity is an air cavity defined by the frame structure and the substrate.

25. The transistor device package of claim 23, wherein the cavity is filled with an encapsulant that extends around the transistor die.

26.-30. (canceled)

31. A passive component assembly, comprising:
one or more passive electrical components on a surface of an interconnect structure, wherein the interconnect structure is configured to electrically couple the one or more passive electrical components to a gate terminal, drain terminal, and/or source terminal of a transistor die;
a mold structure on the one or more passive electrical components on the surface of the interconnect structure; and
one or more conductive pads that are electrically coupled to the one or more passive electrical components and are exposed by the mold structure.

32. The passive component assembly of claim 31, wherein the surface of the interconnect structure comprising the one or more passive electrical components and the mold structure thereon is a first surface, and wherein the interconnect structure comprises a second surface opposite the first surface that is configured to accept the transistor die.

33. The passive component assembly of claim 32, wherein the second surface of the passive component assembly comprises the one or more conductive pads thereon.

34. (canceled)

35. The passive component assembly of claim 31, wherein the one or more conductive pads are arranged in a ground-signal-ground layout.

36. The passive component assembly of claim 31, wherein the one or more passive electrical components are configured to be electrically tested via the one or more conductive pads prior to electrically connecting the transistor die to the passive component assembly.

37.-42. (canceled)
